(19) United States
(12) Patent Application Publication
(10) Pub. No.: US 2026/0123054 A1
(43) Pub. Date: Apr. 30, 2026

(54) INTEGRATED CIRCUIT DEVICE AND METHOD OF FABRICATING THE SAME

(71) Applicant: TAIWAN SEMICONDUCTOR MANUFACTURING COMPANY, LTD., Hsinchu (TW)

(72) Inventors: Chia-Hui CHEN, Hsinchu (TW); Jing-Yu HUNG, Hsinchu (TW); Yu-Kai TSAI, Hsinchu (TW); Chia-Jung CHANG, Hsinchu (TW)

(21) Appl. No.: 19/090,710

(22) Filed: Mar. 26, 2025

Related U.S. Application Data
(60) Provisional application No. 63/714,539, filed on Oct. 31, 2024.

(51) Int. Cl. H10D 89/10; H01L 23/522; H01L 23/528; H10D 84/01

(52) U.S. Cl. CPC H10D 89/10; H10D 84/0149; H10W 20/42; H10W 20/435

(57) ABSTRACT

An integrated circuit device includes a first cell including a first transistor; and a second cell abutting the first cell at a first cell boundary and including at least a portion of a second circuit. The first cell includes one or more pin layers at the first cell boundary, the one or more pin layers including a highest pin layer, the second circuit is connected to a gate of the first transistor by a first conductive path within the first cell, the first conductive path includes a first conductor in a top-most conductive layer among conductive layers forming the first conductive path within the first cell, the top-most conductive layer being a higher layer than the highest pin layer, and the second circuit includes a second conductor connected to the first conductive path at a first pin conductor in a first pin layer among the one or more pin layers.

### PRIORITY

This application claims the benefit of U.S. Provisional Application No. 63/714,539, filed Oct. 31, 2024, which is herein incorporated by reference in its entirety.

### BACKGROUND

The ongoing trend in miniaturizing integrated circuit devices has resulted in progressively smaller and lower power consumption devices that provide increased functionality at high speeds. The miniaturization process has also resulted in increasingly strict design and manufacturing specifications.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a block diagram of an integrated circuit (IC) according to some embodiments.

FIG. 1B is a schematic diagram of an IC device according to some embodiments.

FIG. 2 is a cross-sectional diagram of an IC device according to some embodiments.

FIG. 3A is a schematic cross-sectional view of an intermediate fabrication structure of an IC device according to some embodiments.

FIG. 3B is a schematic cross-sectional view of an intermediate fabrication structure of an IC device according to some embodiments.

FIG. 4A is a schematic view of an IC device according to some embodiments.

FIG. 4B is a partial layout view of an IC device according to some embodiments.

FIG. 4C is a schematic view of an IC device according to some embodiments.

FIG. 5A is a schematic view of an IC device according to some embodiments.

FIG. 5B is a partial layout view of an IC device according to some embodiments.

FIG. 6A is a schematic view of an IC device according to some embodiments.

FIG. 6B is a partial layout view of an IC device according to some embodiments.

FIG. 7 is a flowchart of a method of placement and routing according to some embodiments.

FIG. 8 is a flowchart of a method of fabricating an IC device according to some embodiments.

FIG. 9 is a flowchart of a method of manufacturing an IC device according to some embodiments.

FIG. 10 is a block diagram of an IC device design system according to some embodiments.

FIG. 11 is a block diagram of an IC manufacturing system, and an IC manufacturing flow associated therewith, according to some embodiments.

### DETAILED DESCRIPTION

The following disclosure provides many different embodiments, or examples, for implementing different features of the provided subject matter. Specific examples of components, materials, values, steps, operations, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

One aspect of IC device design and manufacturing includes precautions against device damage from an antenna effect. Antenna effect is a term for charge accumulation, e.g., during a plasma operation during IC device fabrication, that can result in damage to device structures such as a gate dielectric layer, e.g., a gate oxide or a high-k gate layer. Damage from the antenna effect occurs when a charge, which is often higher than a normal operating voltage of the IC device, collects on one or more components of an IC structure during fabrication of the IC device, and the charge causes damage to a structure such as a gate dielectric layer. Such damage can result in yield and reliability issues in the fabrication of IC devices such as metal oxide semiconductor (MOS) IC devices, and can be of particular concern in IC devices that include transistor designs that are isolated from a substrate, e.g., a gate all-around transistor in which an epitaxial structure is isolated by a bottom dielectric isolation, which can limit the ability to discharge charges that accumulate during fabrication. As such, IC device design includes provisions for protecting against damage from the antenna effect, e.g., by routing design, process flow design, and/or circuit design. Such provisions include antenna rules that are evaluated to determine whether an antenna effect will induce damage in part of the IC.

An approach to mitigate against antenna effect damage is to reduce the area of charge-accumulating structures, e.g., metal wiring or other conductive wiring, vias, and the like, that is coupled to a charge-sensitive structure such as a gate dielectric. However, as device structures scale down in size, structures such as gate dielectrics become very small and thus the area of charge-accumulating structures attached thereto should also be scaled down to avoid antenna rule violations (an antenna rule violation may also be referred to as a violation of an antenna design rule check (DRC)). This can constrain routing and/or the size of wiring or the like, posing challenges to the placement and routing of cells in the IC. Another approach to mitigate against antenna effect damage is to reduce or modify process operations that can result in charge accumulation, and/or reorder process operations that can accumulate charge so that they are performed when charge-discharging structures are coupled to the net, e.g., coupled to source/drain regions of a transistor of the net, a diode coupled to the net, or the like. Another approach to mitigate against antenna effect is to add diodes to the net to discharge accumulated charge (such diodes may be referred to as antenna diodes). The addition of antenna diodes should be made in consideration of potential consequences such as timing challenges, routing congestion, parasitic capacitance, and/or parasitic resistance from the diodes. Such approaches can be used singly, in various combinations thereof, and/or in combination with other approaches.

In some embodiments, an integrated circuit design provides for connecting a conductive structure in a second cell, which would otherwise result in an antenna rule violation in an adjoining first cell, using a higher (and thus later-formed) conductive layer in the first cell. In some embodiments, the conductive structure in the second cell is made with a size and/or area that is not limited by the antenna rule for the first cell. In some embodiments, an integrated circuit design provides for connecting a conductive structure in a second cell, which would otherwise result in an antenna rule violation in an adjoining first cell, without using an antenna diode.

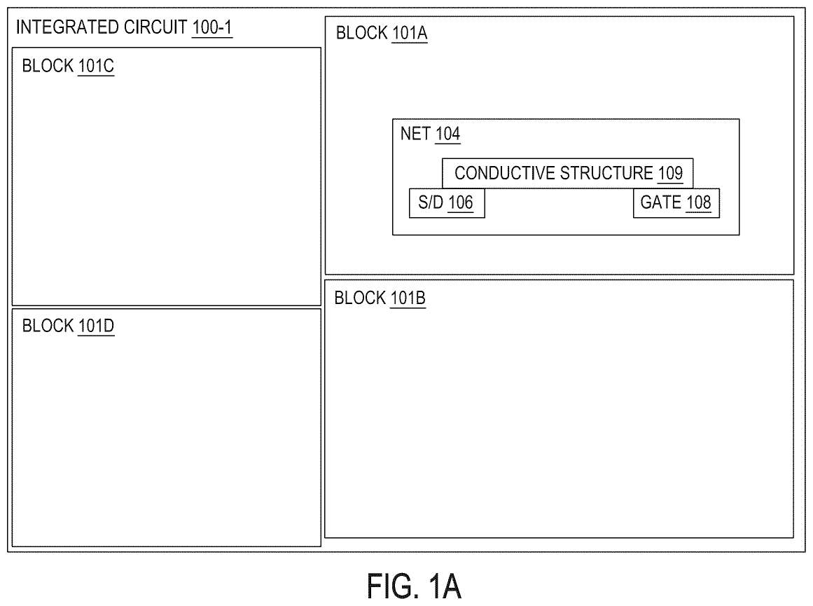

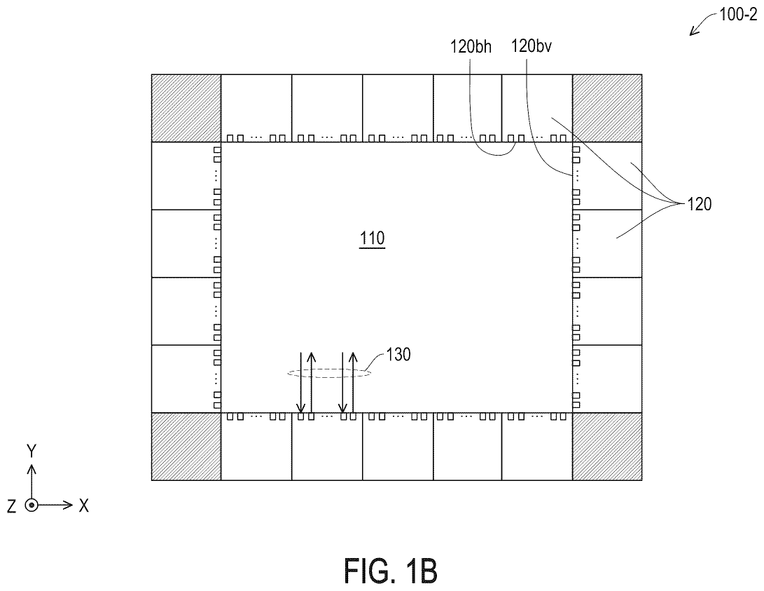

FIG. 1A is a diagram of an integrated circuit (IC) 100-1 according to some embodiments.

In FIG. 1A, IC 100-1 includes cell blocks 101A, 101B, 101C, and 101D (herein, one or more of the cell blocks 101A, 101B, 101C, and 101D may be referred to simply as cell block(s) 101). Each cell block 101 includes one or more nets 104 with a source or drain region 106 (which may be referred to as a source/drain region or S/D region) and a gate 108. In some embodiments, the S/D region 106 is a region where impurities are intentionally introduced into a semiconductor, e.g., by diffusion, implantation, or the like, to modulate properties of the semiconductor. In some embodiments, the source or drain are elements of a transistor such as a MOS field effect transistor (MOSFET). Transistors typically include a source terminal, a drain terminal, and a gate, where the gate is separated from a semiconductor channel region by a gate dielectric layer, e.g., a gate oxide layer. In operation, a voltage at the gate 108 controls a current between the source and drain.

Each net 104 includes portions or all of one or more IC layout cells (not shown in FIG. 1A), e.g., standard cells or IP cells. In some embodiments, the net 104 spans two or more cells that adjoin one another in a layout, e.g., with the S/D region 106 in one cell and the gate 108 in another cell. Standard cells, which can correspond to a, e.g., logical functionality such as NAND, NOR, a latch, or the like, are used as building block of an IC design. In a cell place-and-route methodology, standard cells including a plurality of semiconductor devices are generated and are stored in a standard cell library. IC layouts are then constructed by automatic place and route (APR) tools, which place selected standard cells next to one another in the IC layout.

In FIG. 1A, for the purpose of illustration, the net 104 includes a conductive structure 109 that electrically connects S/D region 106 with a single instance of gate 108 corresponding to an access pin (also referred to as a pin or receiver) of a cell. In some embodiments, the net 104 includes a plurality of pins corresponding to one or more cells.

The conductive structure 109 is one or more conductors arranged to provide electrical connections among the elements of net 104, e.g., the S/D region 106 and the gate 108. In some embodiments, the conductive structure 109 includes conductors (e.g., conductive segments, conductive lines, and the like) in conductive layers (e.g., metal layers, metal-containing layers, and the like) and conductive inter-layer via structures (which may be referred to simply as vias). In some embodiments, the conductive regions of conductive structure 109 are arranged by an APR tool. In some embodiments, the conductive structure 109 that electrically connects the S/D region 106 and the gate 108 is electrically connected to the S/D region 106 and the gate 108 by vias (not shown in FIG. 1A) that are electrical connections between layers in the IC 100-1 that go through the plane of one or more adjacent layers. In some embodiments, the conductive structure 109 includes aluminum, copper, gold, silver, tungsten, or the like.

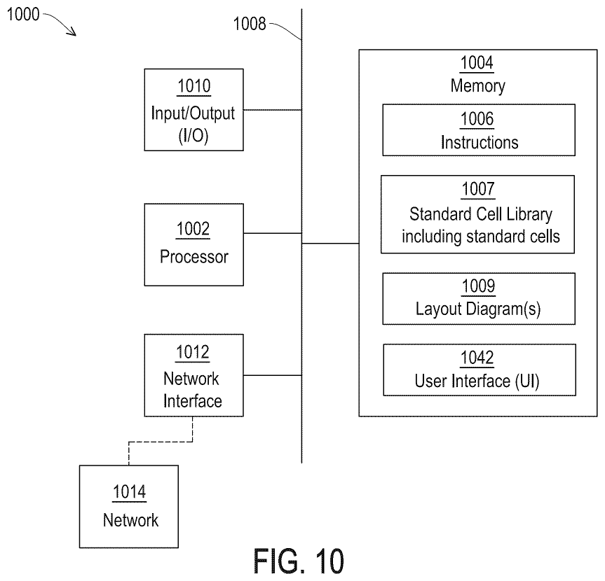

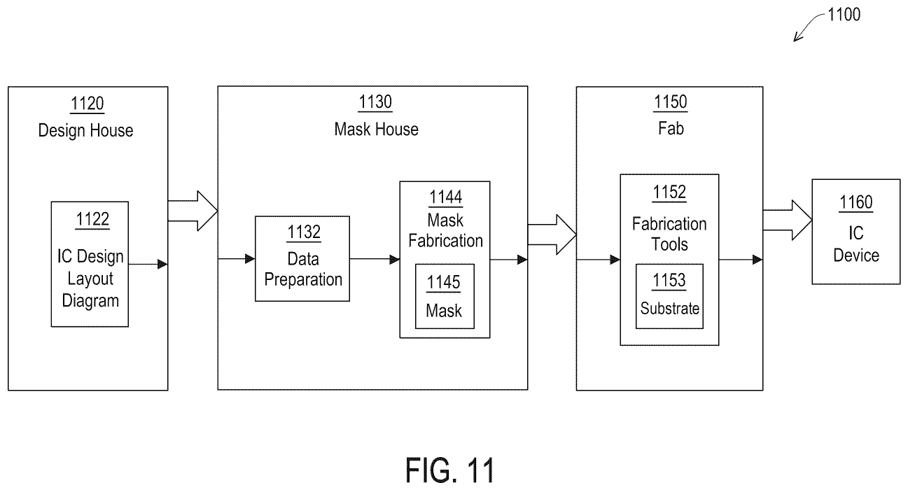

In some embodiments, the IC 100-1 is a set of electronic circuits on one substrate, e.g., a piece of semiconductor material such as a silicon wafer. FIG. 1A shows one net 104 in the IC 100-1, but it will be understood that tens, hundreds, thousands, or even millions of nets are within the IC 100-1. In some embodiments, each cell block 101 includes substantially more than a single instance of net 104. In some embodiments, the IC 100-1 has tens, hundreds, thousands, or even millions of the cell blocks 101 on a single substrate. In some embodiments, each of the cell blocks 101 integrates large numbers of metal oxide semiconductor field-effect transistors (MOSFETs). In some embodiments, the IC 100-1 is designed using an electronic design automation (EDA) system 1000 discussed below with respect to FIG. 10 and/or is manufactured with an IC manufacturing system 1100 discussed below with respect to FIG. 11.

In some embodiments, the cell block 101 is a block of IC layout cells that an APR tool populates based on an algorithm, e.g., an algorithm including one or more iterative operations. In some embodiments, a cell, in the context of an EDA tool, is a representation of a component within a schematic diagram or physical layout of an electronic circuit in software. A cell-based design methodology enables designers to analyze chip designs at varying levels of abstraction.

In FIG. 1A, the net 104 includes at least one driver (e.g., including the S/D region 106) and at least one receiver (e.g., including the gate 108). The gate 108 includes a thin gate dielectric layer. Breakdown or damage to the dielectric layer during fabrication of the IC device can occur if a portion of the net 104 coupled to the gate 108 acquires a voltage higher than the normal operating voltage of the IC 100-1.

A violation of an antenna rule may be referred to as an antenna violation. Antenna rules are often expressed as an allowable ratio of conductive structure area to gate area, e.g., gate dielectric area or gate oxide area. In some embodiments, the area that is counted in determining the conductive structure area is a total area of all conductive structures connected to gate electrodes without being connected to a charge-discharging structure, e.g., a source/drain region. When the IC supports different transistor designs, gate dielectric thickness, gate oxides, or the like (such as a thick gate dielectric layer for a higher voltage transistor and a thin gate dielectric layer for a high performance transistor), then each transistor design, gate dielectric thickness, or the like can have a different antenna rule. Also, there are cumulative rules, where the sum (or partial sum) of the ratios over all conductive structures determines an antenna effect limit or conductive area limit. Also, there are rules that consider the periphery of each structure.

One approach to addressing an antenna violation is to add one or more diodes to a conductive structure that is included in the conductive structure area that is evaluated by, and violates, the antenna rule, e.g., to a portion of the net 104. A diode is a two-terminal electronic component that conducts current primarily in one direction; it has relatively low resistance in the one direction and relatively high resistance in an opposite direction. In some embodiments, the diode (which may be referred to as an antenna diode) has a first terminal coupled to the conductive structure 109 and a second terminal coupled to the device substrate, e.g., as an n-type diffusion or implant in a p-type substrate, as a p-type diffusion or implant in an n-type well, or the like. For example, if the fabrication of the conductive structure 109 were anticipated to cause an antenna violation, one or more antenna diodes (not shown in FIG. 1A) could be connected to the conductive structure 109, e.g., at a location between the S/D region 106 and the gate 108, to diode-couple the conductive structure 109 to the substrate. The diode connected to the conductive structure 109 operates to protect the gate dielectric layer of the gate 108 from breaking down during fabrication of the IC device during an operation in which the S/D region 106 is not yet electrically connected to the gate 108. The addition of one or more antenna diodes to the conductive structure 109 can prevent the violation of the antenna rule without otherwise changing the net 104. However, the addition of antenna diodes can pose timing challenges, routing congestion, parasitic capacitance, and/or parasitic resistance from the antenna diodes.

FIG. 1B is a schematic plan view of an integrated circuit (IC) device 100-2 according to some embodiments.

The IC device 100-2 includes a core cell region 110 and input/output (I/O) cells 120 around edges of the core cell region 110. Core circuits in the core cell region 110 communicate with the I/O cells 120 via interface signals 130. In some embodiments, such interface signals are routed across a horizontal cell boundary 120bh (parallel to the X-axis) that is located where a cell in the core cell region 110 abuts an I/O cell 120 at a horizontal edge (parallel to the X-axis) of the core cell region 110. In some embodiments, such interface signals are routed across a vertical cell boundary 120bv (parallel to the Y-axis) that is located where a cell in the core cell region 110 abuts an I/O cell at a vertical edge (parallel to the Y-axis) of the core cell region 110.

In some embodiments, the core cell region 110 and/or the I/O cells include one or more standard cells. In some embodiments, the core cell region 110 and/or the I/O cells 120 are in one or more of the cell blocks 101 described above.

In the IC device 100-2, circuits that interface between the core cell region 110 and the I/O cells can have relatively long conductors and thus can be relatively more likely to generate a violation of an antenna DRC, as compared to other cells of the IC device 100-2.

As discussed above, the antenna DRC is a check that is performed to avoid device damage, e.g., in the form of damage to a gate dielectric layer (or gate oxide) of a transistor during fabrication of the IC device 100-2. Operations performed during fabrication of the IC device 100-2, e.g., operations involving plasma, can cause charge accumulation on device structures that are electrically connected to the gate, creating a voltage potential across the gate dielectric layer. Excess charge accumulation can cause a breakdown of the gate dielectric layer. Such charge-induced breakdown may be referred to as plasma-induced damage (PID). A violation of the antenna DRC can arise when an area of conductive material, (e.g., metal layers, vias, and the like) exceeds a predetermined ratio relative to an area of the gate dielectric layer. The ratio is set forth as a design rule, which can vary depending on the particular layer of the IC, the gate design, the transistor design, the process node, and similar factors. The antenna DRC is intended to identify and prevent the possibility of exceeding the metal-to-gate dielectric layer area ratio during fabrication. During the design phase, violations of the antenna rule can be solved or mitigated by coupling diodes to the metal structure(s) upon which the charge accumulates, the diodes being configured to discharge the accumulated charges at a voltage that is below a breakdown voltage of the gate dielectric layer connected to the metal structure(s). However, the addition of antenna diodes can impact performance of the resulting IC, e.g., by imposing greater capacitance on the corresponding circuit structure, potentially slowing operation and/or increasing power consumption of the circuit.

Circuits that interface between the core cell region 110 and the I/O cells 120 can generate a violation of an antenna DRC because conductors for signal routing, which are coupled to the transistor, can extend with significant length beyond the cell edge. The length of the signal routing beyond the cell edge results in an increased possibility of charge accumulation. Further, as process nodes develop and transistor structures are reduced in size, the corresponding gate dielectric layer areas also decrease, which in turn leads to the allowable area of connected conductors also being decreased to adhere to the area ratio of the design rule. Additionally, some process nodes implement transistor structures that may be less able to discharge accumulated charge. For example, a gate-all-around (GAA) transistor can include a source/drain epitaxial structure that is isolated from the underlying substrate by a bottom dielectric isolation, which in some cases does not provide an effective antenna discharging junction to the substrate or active region (OD region).

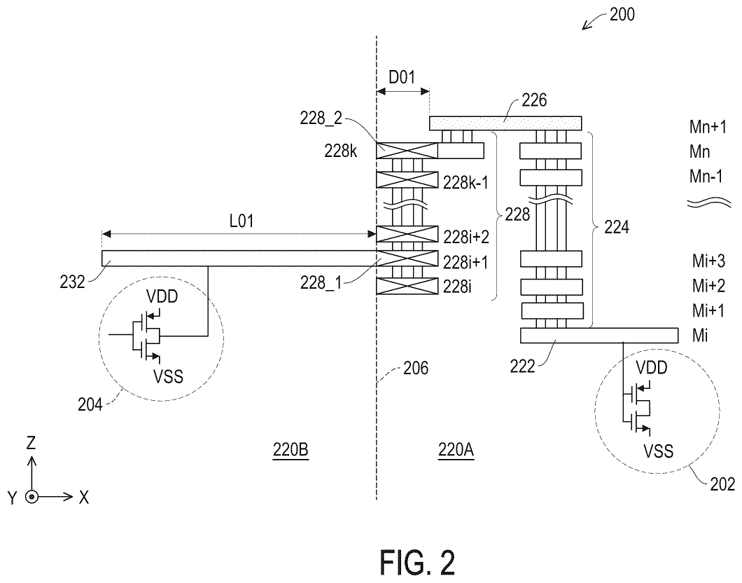

FIG. 2 is a schematic cross-sectional view of an IC device 200 according to some embodiments.

The IC device 200 includes a first active circuit element 202 (e.g., a first transistor, a first pair of transistors, or the like) on a substrate (not shown in FIG. 2) and a second active circuit element 204 (e.g., a second transistor, a second pair of transistors, or the like) on the substrate. The first and second active circuit elements 202, 204 are part of a same net, e.g., the net 104.

The first active circuit element 202 is in a first cell 220A and the second active circuit element 204 is in a second cell 220B that adjoins the first cell 220A at a cell boundary 206, which may also be referred to as an IP cell edge. In some embodiments, the second active circuit element 204 is part of a core circuit and the first active circuit element 202 is part of an I/O circuit. In some embodiments, the second cell 220B is a core circuit cell and the first cell 220A is an I/O cell. In the example in FIG. 2, the cell boundary 206 is located where the first cell 220A adjoins the second cell 220B relative to the X-axis direction, e.g., relative to adjacent locations in a same horizontal row of a layout. In some embodiments, the cell boundary 206 corresponds to a boundary that extends parallel to the Y-axis direction such as the vertical cell boundary 120bv described above. However, embodiments are not limited to cells that abut relative to a horizontal direction in the manner shown in FIG. 2, and are also applicable to cells that abut in a vertical or Y-axis direction.

In the following description of FIG. 2, it will be assumed that the cell boundary 206 extends parallel to the Y-axis and corresponds to a functional or structural interruption in an active region (which extends parallel to the X-axis) in a transistor layer that includes the first and/or second active circuit elements 202, 204. An example of a functional interruption in the active region is a dummy gate structure configured to receive a voltage that inhibits conduction in an underlying portion of the corresponding active region, e.g., inhibits an inversion layer in the underlying portion of the corresponding active region. Examples of a structural interruption in the active region include a physical edge of the active region or a gap in the active region, an insulating structure, a doping region, a diffusion region, or the like that interrupts a first portion of the active region from a second portion of the active region, and the like. In some embodiments, the cell boundary 206 corresponds to a dummy gate structure that does not constitute a functional feature of a transistor (e.g., an isolation dummy gate formed of an insulating material), a continuous oxide diffusion (CNOD) structure, a poly over diffusion edge (PODE) structure, a continuous poly over diffusion edge (CPODE) structure, a boundary isolation region, or the like. In other embodiments, the cell boundary 206 corresponds to a feature or structure that extends parallel to the X-axis. In some embodiments, the cell boundary 206 corresponds to a power rail in an MO conductor layer (a first metal layer over a gate or poly layer). In other embodiments, the cell boundary corresponds to another conductor in the MO layer. In other embodiments, the cell boundary corresponds to features in a layer or layers that are above the transistor layer or above the MO layer. Boundaries of cells or cell regions can also be discerned in other ways than those described above.

In the discussion that follows, it will be assumed that the first active circuit element 202 includes at least one transistor having a gate dielectric layer that is to be evaluated according to an antenna DRC during a design of the IC device 200 prior to fabrication of the IC device 200. Merely by way of example, the first active circuit element 202 and the second active circuit element 204 are shown with a pair of transistors in FIG. 2. However, it will be understood that the number of transistors can be suitably varied and one or both of the first active circuit element 202 and/or the second active circuit element 204 include one transistor in some embodiments, or more than two transistors in other embodiments.

In FIG. 2, the IC device 200 includes a conductive layer Mi having a first conductor 222. The first conductor 222 is connected to a gate of a first transistor in the first active circuit element 202. The first conductor 222 and the first transistor are both in the first cell 220A. The first transistor in the first active circuit element 202 has a gate dielectric layer to be evaluated under an antenna rule, which may be referred to as a target gate dielectric layer.

In some embodiments, the conductive layer Mi is a first conductive layer MO over a gate layer of the IC device 200. A via structure in a via layer (e.g., a via-gate (VG) layer (not shown)) under the conductive layer Mi connects the gate of the first transistor to the conductive layer Mi.

In the completed IC device 200, the first conductor 222, and thus the first transistor having the target gate dielectric layer, the gate of which is connected to the first conductor 222, are ultimately connected to the second active circuit element 204 in the second cell 220B. However, during fabrication of the IC device 200, the first conductor 222, and thus the target gate dielectric layer, are connected to a relatively small portion of the overall conductive structures that form the connection between the first conductor 222 and the second active circuit element 204 in the second cell 220B.

In further detail, the first cell 220A includes a stack 224 of conductors and vias that couples the first conductor 222 to a second conductor 226. The second conductor 226 is coupled to a pin structure 228.

In FIG. 2, the IC device 200 includes conductive layers Mi, Mi+1, Mi+2, Mi+3, . . . , Mn, and Mn+1. The conductive layers Mi˜Mn+1 are, e.g., metal layers.

The stack 224 includes conductors in conductive layers Mi+1˜Mn. Conductive vias in via layers extend between adjacent ones of the conductors in conductive layers Mi+1˜Mn. In other embodiments, the stack 224 includes, e.g., one or more deep vias that skip one or more of the conductive layers Mi+1 through Mn. Although FIG. 2 illustrates conductive layers Mi, Mi+1, Mi+2, Mi+3, . . . , Mn, and Mn+1, in other embodiments more or fewer conductive layers are provided.

The pin structure 228 includes pin conductors in pin layers 228i˜k of the first cell 220A. The pin structure 228 also includes vias connecting the pin conductors. In some embodiments, the pin structure 228 includes one or more deep vias that skip one or more of the pin layers 228i˜k. The pin layers 228i˜k include pin layers 228i, 228i+1, 228i+2, . . . , 228k−1, and 228k, with pin layer 228i being a lowest pin layer (closest to the substrate) and pin layer 228k being a highest pin layer. Although FIG. 2 illustrates a plurality of pin layers, in other embodiments more or fewer pin layers are provided.

In FIG. 2, the pin structure 228 includes a first pin conductor 2281 in pin layer 228i+1, a second pin conductor 2282 in pin layer 228k, and pin conductors and vias extending between first pin conductor 228_1 and the second pin conductor 228_2.

The pin layers 228i˜k correspond to the conductive layers Mi+2˜Mn, i.e., pin layer 288i corresponds to conductive layer Mi+2. However, this is merely an example and the pin layer 288i can correspond to a conductive layer lower than Mi+2 (e.g., Mi+1) or a conductive layer higher than Mi+2 (e.g., Mi+3).

The pin conductors 228_1, 2282 adjoin the cell boundary 206, and the second conductor 226 is coupled to the highest pin conductor 228_2 while being spaced apart from the cell boundary 206 by a distance D01. Among other things, spacing the second conductor 226 apart from the cell boundary 206 allows the second conductor 226 to be made smaller. Making the second conductor 226 smaller reduces the area of the second conductor 226 that can accumulate charge during fabrication of the IC device 200.

In the second cell 220B, a third conductor 232 extends from the pin conductor 228_1. In some embodiments, the third conductor 232 and the pin conductor 228_1 are formed as a monolithic conductor, e.g., a single metal line. The third conductor 232 extends with a length L01 in the second cell 220B. Although the third conductor 232 is in the pin layer 228i+1 (corresponding to conductive layer Mi+3) in FIG. 2, this is merely an example; the third conductor can be in any of the pin layers 228i-228k.

In some embodiments, the length L01 is sufficiently large that a combined charge-accumulating area of the third conductor 232, the pin structure 228, the second conductor 226, the stack 224, and the first conductor 222 exceeds an antenna DRC for a gate coupled to the first conductor 222. In some embodiments, a net that includes the second active circuit element 204, the third conductor 232, the pin structure 228, the second conductor 226, the stack 224, the first conductor 222, and the first active circuit element 202 is free of an antenna diode.

In the IC device 200, the second conductor 226 is in a higher layer (layer Mn+1) than a highest conductor in the pin structure 228, i.e., the second conductor 226 is in a conductive layer that is higher than the highest pin conductor 228_2 and the highest pin layer 228k corresponding to conductive layer Mn. Conductive layers below the conductive layer Mn+1, i.e., conductive layers of Mn and below, are not used to couple the first conductor 222 to the pin layers 228i˜k. Stated differently, the second conductor 226 is a highest conductor, and thus a last-formed conductor, among conductors that couple the target gate dielectric layer to the second active circuit element 204.

That is, the net that includes the second active circuit element 204, the third conductor 232, the pin structure 228, the second conductor 226, the stack 224, the first conductor 222, and the first active circuit element 202 uses a layer that is Mn+1 (or a higher layer) for a final layer of the connection structure between the target gate dielectric layer (in the first active circuit element) and the pin conductors of the pin layers 228i-228k. By forming the second conductor 226 as a highest conductor among conductors that couple the target gate dielectric layer to the second active circuit element 204, the design of the IC device 200 helps to avoid a violation of an antenna rule (i.e., a DRC violation) by reducing the area of conductive structures coupled to the target gate dielectric area during fabrication of the IC device 200. Reducing the area of conductive structures coupled to the target gate dielectric area during fabrication of the IC device 200 provides advantages such as increased design flexibility, e.g., by increasing the number of available options for routing, and fewer antenna diodes.

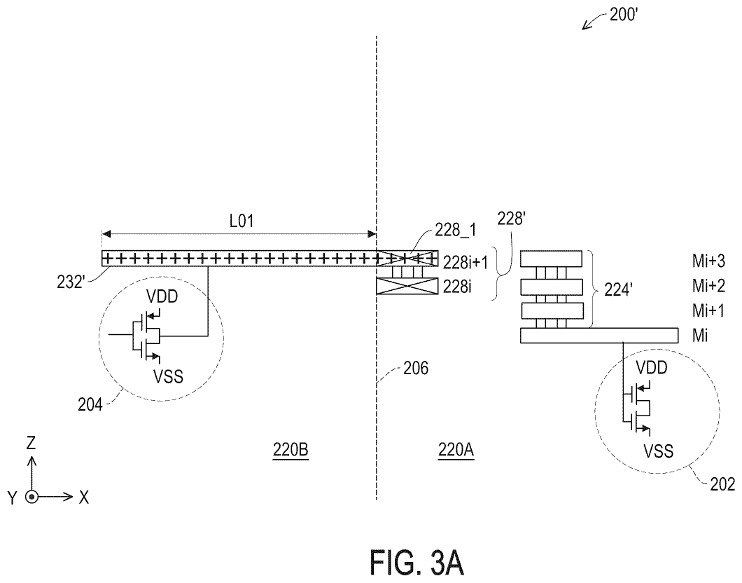

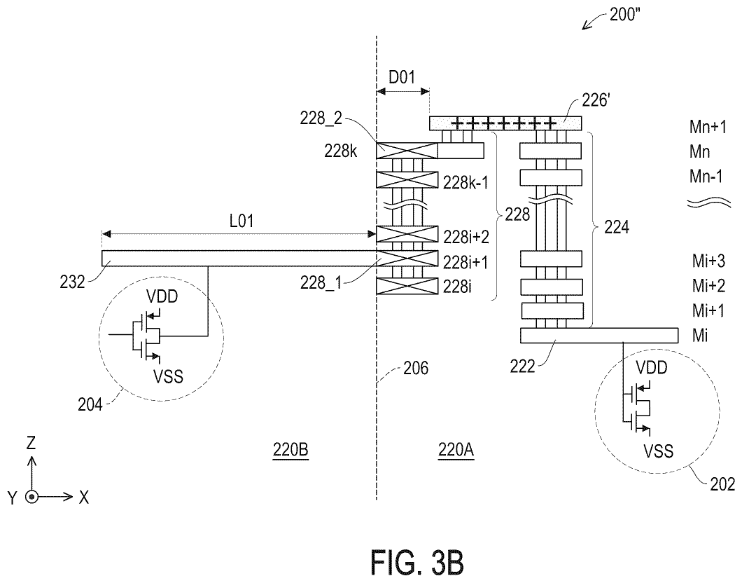

FIG. 3A is a schematic cross-sectional view of an intermediate fabrication structure 200′ of the IC device 200 according to some embodiments.

In FIG. 3A, conductive structures of the stack 224 of conductors and vias and the pin layers 228i˜k of FIG. 2 have been partially formed. In detail, some of the conductors and vias in the stack 224 have been formed, up through the conductive layer Mi+3. Also, some of the conductors and vias in the pin structure 228 have been formed, up through the pin layer 228i+1, which corresponds to the conductive layer Mi+3. Conductive layers and vias above the conductive layer Mi+3 have not yet been formed in FIG. 3A. The stack 224 of FIG. 2 is therefore shown as intermediate stack 224′ in FIG. 3A, and the pin layers 228i˜k of FIG. 2 are shown as intermediate pin structure 228′ in FIG. 3A. The third conductor 232 of FIG. 2 is in the process of being formed and is shown as an intermediate third conductor 232′ in FIG. 3A.

In the IC device 200 in FIG. 2, the pin layers 228i˜k are connected to the second active circuit element 204 by way of the third conductor 232 having the length L01 in the conductive layer Mi+3 in the second cell 200B. In the intermediate fabrication structure 200′ of FIG. 3A, the intermediate third conductor 232′ is being formed but the intermediate third conductor 232′ is not yet connected to the first active circuit element 202. Accordingly, charges that accumulate on the intermediate third conductor 232′ during fabrication (shown as a series of plusses (‘+’) on the intermediate third conductor 232′ in FIG. 3A) due to plasma processing or the like are not able to affect the first active circuit element 202. Stated differently, an antenna DRC for a gate dielectric layer in the first active circuit element 202 for the intermediate fabrication structure 200′ in FIG. 3A does not take into account the charges (‘+’) on the intermediate third conductor 232′. Accordingly, the length L01 of the third conductor 232 in the final IC device 200 is not limited by concerns of violating an antenna DRC for the first active circuit element 202 for the intermediate third conductor 232′ in FIG. 3A. Accordingly, the third conductor 232 can be made long in the second cell 220B without violating an antenna DRC for a gate in the first active circuit element 202. This enables greater routing flexibility by expanding the available range of design lengths for the third conductor 232, and does so without imposing the need to add an antenna diode to the third conductor 232 for protection of the first active circuit element 202.

FIG. 3B is a schematic cross-sectional view of an intermediate fabrication structure 200″ of the IC device 200 according to some embodiments.

In FIG. 3B, the fabrication of the third conductor 232 has been completed. In some embodiments, after the completion of each conductor or conductive layer, a charge neutralization operation is performed to prevent continuous charge accumulation. In FIG. 3B, the accumulated charges (‘+’) on the intermediate third conductor 232′ in the intermediate fabrication structure 200′ of FIG. 3A have been discharged. Discharging the accumulated charges on the third conductor 232 prevents the accumulated charges from implicating an antenna rule for the target gate dielectric in the first active circuit element 202.

In FIG. 3B, conductive structures of the stack 224 of conductors and vias and the pin layers 228i˜k of FIG. 2 have completed and the second conductor 226 in conductive layer Mn+1 is in the process of being fabricated; this is indicated in FIG. 3B as intermediate second conductor 226′.

In FIG. 3B, a plasma fabrication process or the like results in accumulation of charges (‘+’) on the intermediate second conductor 226′. However, the design length of the second conductor 226 is controllable in IP and can be made shorter (reducing a charge-accumulating area) by the spacing D01 from the cell boundary 206. The shorter length of the second conductor 226 reduces a charge-accumulating area and the amount of accumulated charges (‘+’) on the intermediate second conductor 226′. Further, in FIG. 3B, the intermediate second conductor 226′ is coupled to a S/D region of a transistor in the second active circuit element 204, which in some embodiments can operate to discharge the accumulated charges.

As described above, the IC device 200 is designed, structured, and fabricated such that the intermediate fabrication structures 200′, 200″ do not expose the first active circuit element 202 to a charge-accumulating conductive area of the third conductor 232 and, thus, an antenna rule for a gate in the first active circuit element 202 does not constrain the length L01 of the third conductor 232 in the second cell 220B. This allows aspects of the features of the second cell 220B to be chosen independently of features of the first cell 220A, allowing greater flexibility in the design or selection of the first and second cells 200A, 200B, e.g., in terms of the length L01 of the third conductor 232 in the second cell 220B. In some embodiments, the length L01 of the third conductor 232 in conductive layer Mi+3 in the second cell 220B is greater than a length of any conductor in conductive layer Mi+3 in the first cell 220A. In some embodiments, the length L01 of the third conductor 232 is greater than a length of any conductor in any conductive layer in the first cell 220A.

The design flexibility discussed above can be extended to any of the conductive layers in the pin layers 228i˜k, i.e., in conductive layers below the conductive layer Mn+1, due to the fabrication of the second conductor 226 as the highest and last conductor (in the conductive layer Mn+1 or a higher layer) among conductors that couple the target gate dielectric layer of the first active circuit element 202 to the second active circuit element 204. Thus, the design of the IC device 200 helps to avoid a violation of an antenna rule, e.g., in the intermediate fabrication structures 200′, 200′ (or during another fabrication stage), while providing increased design flexibility and/or reducing the number of antenna diodes that are included in the IC device 200.

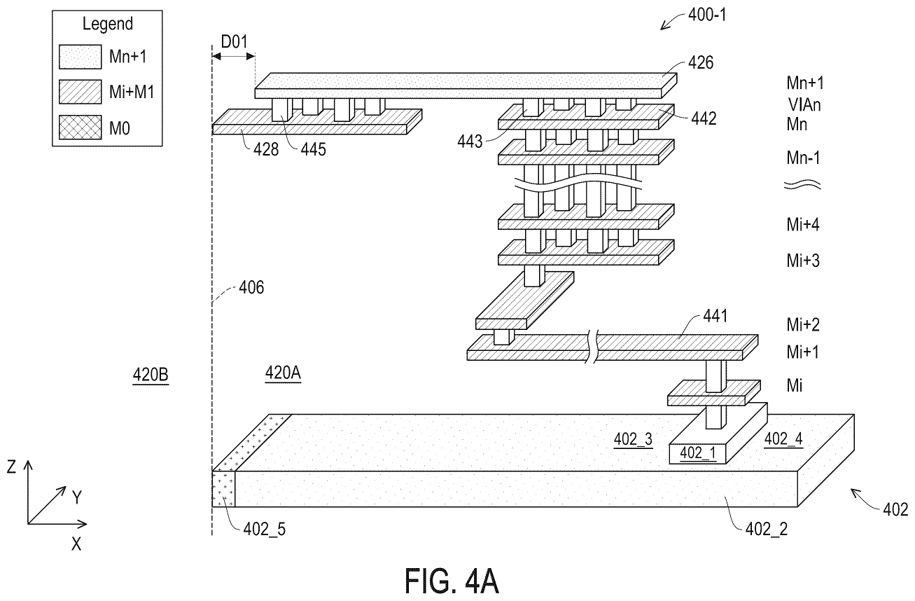

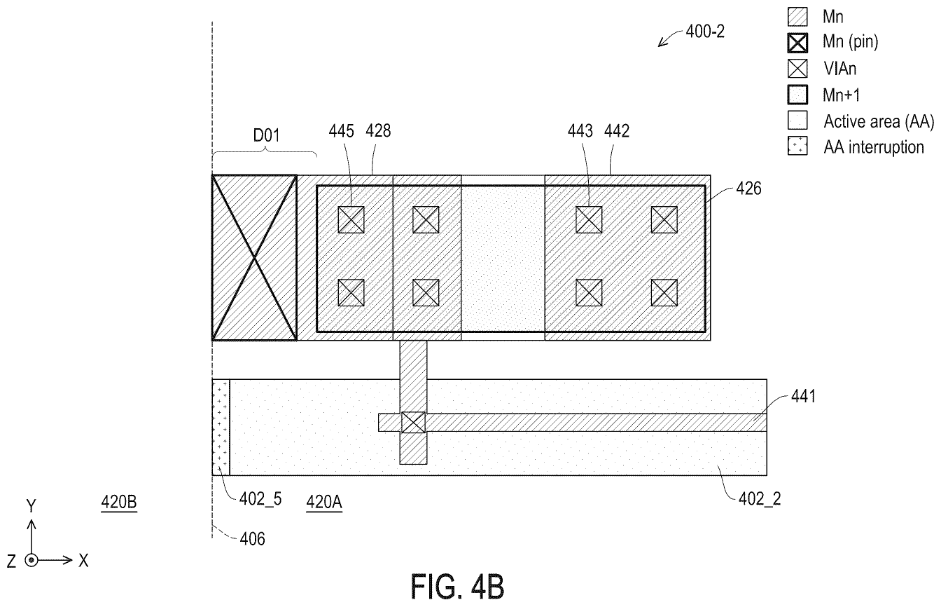

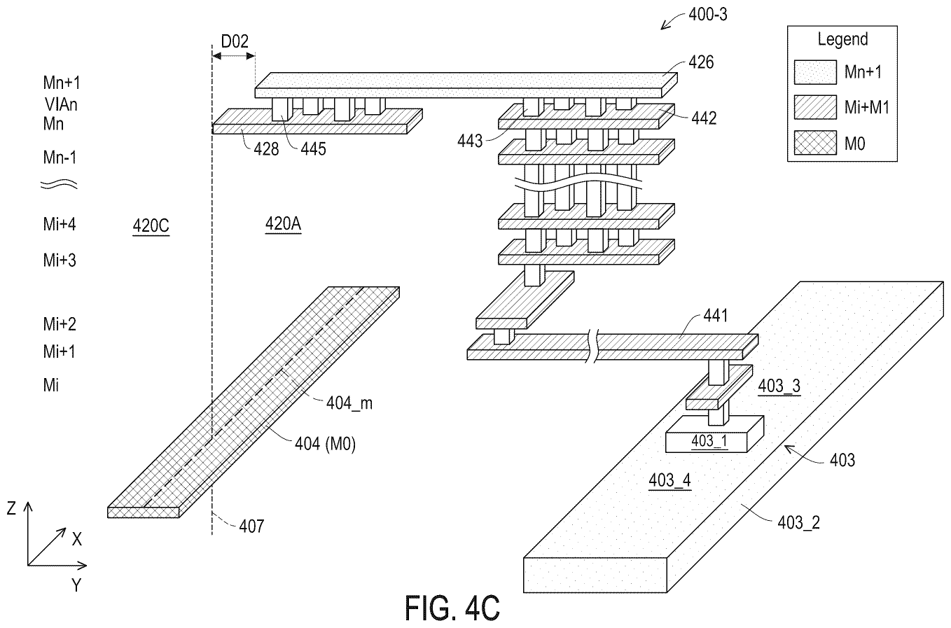

FIG. 4A is a schematic view of an IC device 400-1 according to some embodiments. FIG. 4B is a partial layout view of an IC device 400-2 according to some embodiments.

Elements of IC devices 400-1, 400-2 having a similar structure and function as elements of IC device 200 have a same identifying numeral, incremented by 200, unless stated otherwise or otherwise apparent.

Referring to FIG. 4A, the IC device 400-1 according to some embodiments includes a first cell 420A and a second cell 420B, which adjoin at a cell boundary 406, which extends parallel to the Y-axis. The first cell 420A includes a transistor 402 having a gate 4021, e.g., a polysilicon gate, a high-k metal gate, or the like, over an active area 402_2, and a source 402_3 and a drain 402_4 in the active area 402_2. An active area interruption 402_5 interrupts the active area 402_2 at the cell boundary 406. In some embodiments, the active area interruption 402_5 corresponds to a dummy gate structure, a doping region, an insulating material, or the like. In some embodiments, the cell boundary 406 corresponds to a place-and-route boundary defining a region in which placement is done and where routing is constrained to. The transistor 402 is shown as a planar structure but the transistor 402 has other configurations in other embodiments, e.g., FinFet, gate all-around (GAA), complementary FET (CFET), or the like.

The gate 4021 is coupled to a pin conductor 428 at the cell boundary 406. The pin conductor 428 is in conductive layer Mn. Although not shown in FIG. 4A, in some embodiments, in the second cell 420B a conductor (e.g., having the length L01 and corresponding to the third conductor 232 of the IC device 200) extends in the conductive layer Mn in the second cell 420B from the pin conductor 428 in the first cell 420A.

As compared to the IC device 200, a pin-out for the transistor 402 is provided in the conductive layer Mn in the IC device 400-1. That is, IC device 400-1 uses a higher pin-out layer than the IC device 200, which results in a simpler design in the IC device 400-1 as compared to the IC device 200, which has a plurality of layers in the pin structure 228.

The pin conductor 428 is coupled to the transistor 402 by a plurality of conductors and vias, the last-formed conductor of which is a conductor 426 in a conductive layer Mn+1 that is higher than the layer of the pin conductor 428. Thus, the conductor 426 is formed after the pin conductor 428 and after a conductor in the conductive layer Mn in the second cell 420B. By forming the conductor 426 in a layer (layer Mn+1) that is higher than a layer of the pin-out (layer Mn), a conductor in the second cell 420B in the pin-out layer (i.e., layer Mn in second cell 420B) can have a length (e.g., the length L01) that is not limited by an antenna rule for the transistor 402. Further, the conductor 426 can be made shorter, e.g., to reduce a charge-accumulating area in the first cell 420A, by the distance D01 between the cell boundary 406 and the conductor 426.

In FIG. 4A, the IC device 400-1 is shown as having conductors in conductive layers Mi through Mn+1, with vias in layers therebetween (e.g., in via layer VIAn between conductive layers Mn and Mn+1). However, a greater number of conductive layers is used in some embodiments, and a smaller number of conductive layers is used in other embodiments. Further, the pin-out of the transistor 402 is in a higher layer than the conductive layer Mn in some embodiments (although below the last-formed conductor 426, which may be in a higher layer than Mn+1), and is in a lower layer than the conductive layer Mn in other embodiments. Also, in FIG. 4A, the IC device 400-1 is shown as having four vias 445 extending vertically (parallel to the Z axis) between the pin conductor 428 and the overlying conductor 426. In some embodiments, fewer than four vias 445 are used, e.g., one via 445. In other embodiments, more than four vias 445 are used. Likewise, a number of vias 443 between conductor 442 in conductive layer Mn (at an opposite end of the conductor 426 from the pin conductor 428) is four in FIG. 4A, but is more or less in other embodiments. Also, the lengths of conductors in the conductive layers Mi˜Mn can be varied as desired. For example, whereas the IC device 200 includes a relatively long conductor in conductive layer Mi, the IC device 400-1 includes a relative short conductor in the conductive layer Mi and includes a longer conductor 441 in conductive layer Mi+1.

Referring to IC device 400-2 of FIG. 4B, the pin conductor 428 is under the conductor 426 but a region of the pin conductor 428, corresponding to distance D01 between the cell boundary 406 and the conductor 426, is not overlapped by the conductor 426. The conductor 426 can be made shorter by the distance D01 by instead extending the pin conductor 428 from the cell boundary. This has an advantage of reducing a charge-accumulating area of the conductor 426. Also, because at the time of fabrication of the pin conductor 428 it is not connected to the transistor 402 (due to the conductor 426 not having been formed yet), the length of the pin conductor 428 does not implicate the antenna rule of the transistor 402 when the pin conductor 428 is being formed.

In FIG. 4B, the legend identifies Mn, Mn (pin), VIAn, and Mn+1. Mn and Mn+1 are conductive layer n (e.g., metal layer n) and conductive layer n+1 (e.g., metal layer n+1). VIAn is via layer n.

The Mn, VIAn, and Mn+1 features define shapes that will become physical structures (e.g., metal structures) in the final manufactured device (e.g., a die or chip), and help to ensure that the structures (e.g., metal connections) are correctly formed during fabrication.

The legend Mn (pin) identifies a pin layer, which is used to specify connection points or pins on the conductive layer Mn. Pins can be named as desired. In some embodiments, the pins are used in layout versus schematic (LVS) and automatic placement and routing (APR) processes, where the pins help ensure that the layout matches the intended schematic by verifying the connectivity and functionality of the designed circuit.

FIG. 4C is a schematic view of an IC device 400-3 according to some embodiments.

Elements of IC device 400-3 having a similar structure and function as elements of IC device 200 have a same identifying numeral, incremented by 200, unless stated otherwise or otherwise apparent.

Referring to FIG. 4C, the IC device 400-3 according to some embodiments includes a first cell 420A and a third cell 420C, which adjoin at a cell boundary 407, which extends parallel to the X-axis.

The cell boundary 407 is perpendicular to the cell boundary 406 of FIG. 4A. Whereas in FIG. 4A, the cell boundary 406 corresponds to the active area interruption 4025 extending parallel to the Y-axis, in FIG. 4C the cell boundary 407 corresponds to a power rail 404 extending parallel to the X-axis in the first conductor layer MO, which is a first conductor layer (e.g., metal layer) over a gate or poly layer. In some embodiments, the cell boundary 407 corresponds to a midline of the power rail 404 such that one half of the width of the power rail 404 is in the first cell 402A and another half of the width of the power rail 404 is in the third cell 420C. In some embodiments, the cell boundary 407 corresponds to a place-and-route boundary defining a region in which placement is done and where routing is constrained to.

In FIG. 4A described above, the first and second cells 420A and 420B adjoin each other in a same row of a layout (which rows extends parallel to the X-axis), and the active area interruption 402_5 corresponds to a vertical cell boundary (parallel to the Y-axis) in the layout (between the first and second cells 420A and 420B), while in FIG. 4C the first and third cells 420A and 420C adjoin each other in respective rows of a layout (the rows each extending parallel to the X-axis and being adjacent in the Y-axis direction), and the power rail 404 corresponds to a horizontal cell boundary (parallel to the X-axis) in the layout (where the first and third cells 420A and 420C adjoin).

The first cell 420A includes a transistor 403 having a gate 4031, e.g., a polysilicon gate, a high-k metal gate, or the like, over an active area 403_2, and a source 403_3 and a drain 403_4 in the active area 403_2. The transistor 403 is shown as a planar structure but the transistor 403 has other configurations in other embodiments, e.g., FinFet, gate all-around (GAA), complementary FET (CFET), or the like.

The gate 4031 is coupled to the pin conductor 428 at the cell boundary 407. The pin conductor 428 is in the conductive layer Mn. Although not shown in FIG. 4C, in some embodiments, in the third cell 420C a conductor (e.g., having the length L01 and corresponding to the third conductor 232 of the IC device 200) extends in the conductive layer Mn in the third cell 420C from the pin conductor 428 in the first cell 420A.

As compared to the IC device 200, a pin-out for the transistor 403 is provided in the conductive layer Mn in the IC device 400-3. That is, IC device 400-3 uses a higher pin-out layer than the IC device 200, which results in a simpler design in the IC device 400-3 as compared to the IC device 200, which has a plurality of layers in the pin structure 228.

The pin conductor 428 is coupled to the transistor 403 by a plurality of conductors and vias, the last-formed conductor of which is the conductor 426 in a conductive layer Mn+1 that is higher than the layer of the pin conductor 428. Thus, the conductor 426 is formed after the pin conductor 428 and after a conductor in the conductive layer Mn in the third cell 420C. By forming the conductor 426 in a layer (layer Mn+1) that is higher than a layer of the pin-out (layer Mn), a conductor in the third cell 420C in the pin-out layer (i.e., layer Mn in third cell 420C) can have a length (e.g., the length L01) that is not limited by an antenna rule for the transistor 403. Further, the conductor 426 can be made shorter, e.g., to reduce a charge-accumulating area in the first cell 420A, by a distance D02 between the cell boundary 407 and the conductor 426.

In FIG. 4C, the IC device 400-3 is shown as having conductors in conductive layers Mi through Mn+1, with vias in layers therebetween (e.g., in via layer VIAn between conductive layers Mn and Mn+1). However, a greater number of conductive layers is used in some embodiments, and a smaller number of conductive layers is used in other embodiments. Further, the pin-out of the transistor 403 is in a higher layer than the conductive layer Mn in some embodiments (although below the last-formed conductor 426, which may be in a higher layer than Mn+1), and is in a lower layer than the conductive layer Mn in other embodiments. Also, in FIG. 4C, the IC device 400-3 is shown as having four vias 445 extending vertically (parallel to the Z axis) between the pin conductor 428 and the overlying conductor 426. In some embodiments, fewer than four vias 445 are used, e.g., one via 445. In other embodiments, more than four vias 445 are used. Likewise, a number of vias 443 between conductor 442 in conductive layer Mn (at an opposite end of the conductor 426 from the pin conductor 428) is four in FIG. 4C, but is more or less in other embodiments. Also, the lengths of conductors in the conductive layers Mi˜Mn can be varied as desired. For example, whereas the IC device 200 includes a relatively long conductor in conductive layer Mi, the IC device 400-3 includes a relative short conductor in the conductive layer Mi and includes a longer conductor 441 in conductive layer Mi+1.

Referring to IC device 400-3 of FIG. 4C, the pin conductor 428 is under the conductor 426 but a region of the pin conductor 428, corresponding to the distance D02 between the cell boundary 407 and the conductor 426, is not overlapped by the conductor 426. The conductor 426 can be made shorter by the distance D02 by instead extending the pin conductor 428 from the cell boundary. This has an advantage of reducing a charge-accumulating area of the conductor 426. Also, because at the time of fabrication of the pin conductor 428 it is not connected to the transistor 403 (due to the conductor 426 not having been formed yet), the length of the pin conductor 428 does not implicate the antenna rule of the transistor 403 when the pin conductor 428 is being formed.

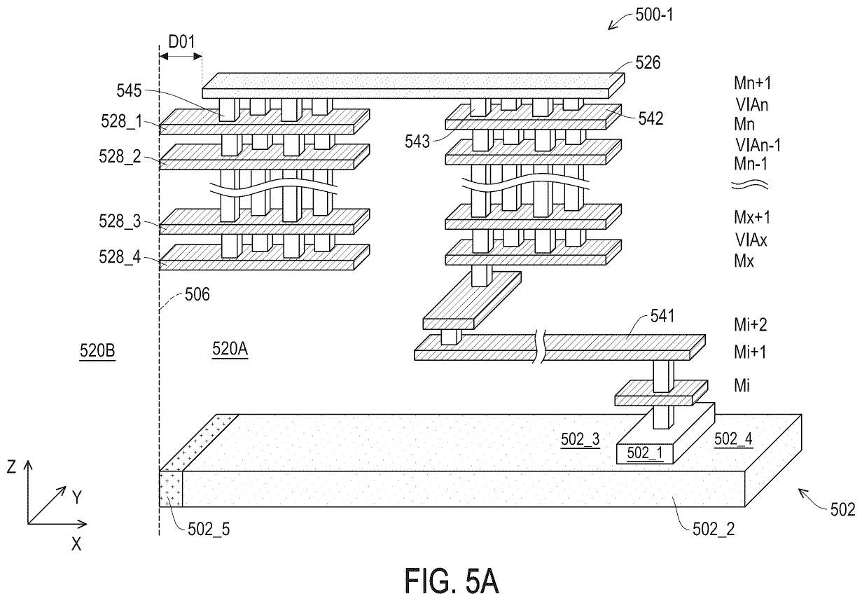

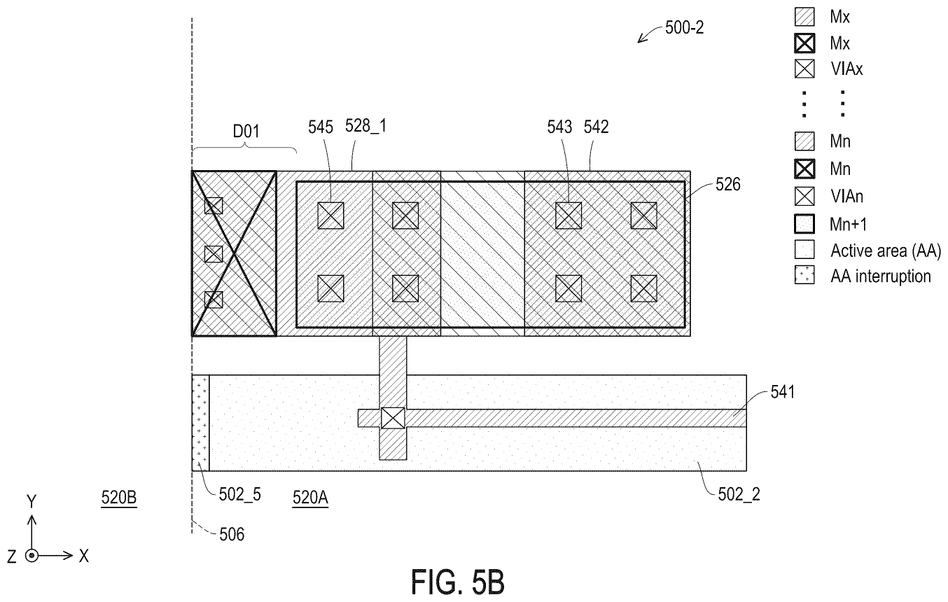

FIG. 5A is a schematic view of an IC device 500-1 according to some embodiments. FIG. 5B is a partial layout view of an IC device 500-2 according to some embodiments.

Elements of IC devices 500-1, 500-2 having a similar structure and function as elements of IC device 200 have a same identifying numeral, incremented by 300, unless stated otherwise or otherwise apparent.

Referring to FIG. 5A, the IC device 500-1 according to some embodiments includes a first cell 520A and a second cell 520B, which adjoin at a cell boundary 506. The first cell 520A includes a transistor 502 having a gate 502_1, e.g., a polysilicon gate, a high-k metal gate, or the like, over an active area 502_2, and a source 502_3 and a drain 502_4 in the active area 502_2. An active area interruption 502_5 interrupts the active area 502_2 at the cell boundary 506. In some embodiments, the active area interruption 502_5 corresponds to a dummy gate structure, a doping region, an insulating material, or the like. In some embodiments, the cell boundary 506 corresponds to a place-and-route boundary defining a region in which placement is done and where routing is constrained to. The transistor 502 is shown as a planar structure but the transistor 502 has other configurations in other embodiments, e.g., FinFet, gate all-around (GAA), complementary FET (CFET), or the like.

The gate 5021 is coupled to pin conductors 528_1˜528_4 at the cell boundary 506. The pin conductor 528_1 is in conductive layer Mn, the pin conductor 528_2 is in conductive layer Mn−1, the pin conductor 528_3 is in conductive layer Mx+1 (x+1 is less than n−1, i.e., a lower layer), and the pin conductor is in conductive layer Mx. Although not shown in FIG. 5A, in some embodiments, in the second cell 520B one or more conductors (e.g., having the length L01 and corresponding to the third conductor 232 of the IC device 200) extend in the corresponding conductive layers Mn, Mn−1, Mx+1, and/or Mx in the second cell 520B from the pin conductors 528_1˜528_4 in the first cell 520A.

In various embodiments, a pin-out for the transistor 502 is provided in any of the conductive layers Mn, Mn−1, Mx+1, and/or Mx in the IC device 500-1. By forming multiple pin-out conductors, there are multiple selections and flexibilities for electrical connections in the IC device 500-1.

The pin conductors 528_1˜528_4 are coupled to the transistor 502 by a plurality of conductors and vias, the last-formed conductor of which is a conductor 526 in a conductive layer Mn+1 that is higher than the highest pin-out layer, i.e., higher than any of the pin conductors 528_1˜528_4. Thus, the conductor 526 is formed after the pin conductor 528_1 and after any corresponding conductor(s) in the conductive layers Mn, Mn−1, Mx+1, and/or Mx in the second cell 520B. By forming the conductor 526 in a layer (layer Mn+1) that is higher than a highest layer of the pin structure (layer Mn), a conductor in the second cell 520B in the any of the pin-out layers (i.e., in any of conductive layers Mn, Mn−1, Mx+1, and/or Mx in second cell 520B) can have a length (e.g., the length L01) that is not limited by an antenna rule for the transistor 502. Further, the conductor 526 can be made shorter, e.g., to reduce a charge-accumulating area in the first cell 520A, by the distance D01 between the cell boundary 506 and the conductor 526.

In FIG. 5A, the IC device 500-1 is shown as having conductors in conductive layers Mi through Mn+1, with vias in layers therebetween (e.g., in via layer VIAn between conductive layers Mn and Mn+1, and in via layer VIAx between conductive layers Mx and Mx+1). However, a greater number of conductive layers is used in some embodiments, and a smaller number of conductive layers is used in other embodiments. Further, the pin-out of the transistor 502 is in a higher layer than the conductive layer Mn in some embodiments (although below the last-formed conductor 526, which may be in a higher layer than Mn+1), and is in a lower layer than the conductive layer Mn in other embodiments. Also, in FIG. 5A, the IC device 500-1 is shown as having four vias 545 extending vertically (parallel to the Z axis) between the pin conductor 528_1 and the overlying conductor 526. In some embodiments, fewer than four vias 545 are used, e.g., one via 545. In other embodiments, more than four vias 545 are used. Likewise, a number of vias 543 between conductor 542 in conductive layer Mn (at an opposite end of the conductor 526 from the pin conductor 528_1) is four in FIG. 5A, but is more or less in other embodiments. Also, the lengths of conductors in the conductive layers Mi˜Mn can be varied as desired. For example, whereas the IC device 200 includes a relatively long conductor in conductive layer Mi, the IC device 500-1 includes a relative short conductor in the conductive layer Mi and includes a longer conductor 541 in conductive layer Mi+1.

Referring to IC device 500-2 of FIG. 5B, the pin conductor 528_1 is under the conductor 526 but a region of the pin conductor 528_1, corresponding to distance D01 between the cell boundary 506 and the conductor 526, is not overlapped by the conductor 526. The conductor 526 can be made shorter by the distance D01 by instead extending the pin conductor 528_1 from the cell boundary. This has an advantage of reducing a charge-accumulating area of the conductor 526. Also, because at the time of fabrication of the pin conductor 528_1 it is not connected to the transistor 502 (due to the conductor 526 not having been formed yet), the length of the pin conductor 528_1 does not implicate the antenna rule of the transistor 502 when the pin conductor 5281 is being formed. This also applies to the other pin conductors 528_2˜528_4.

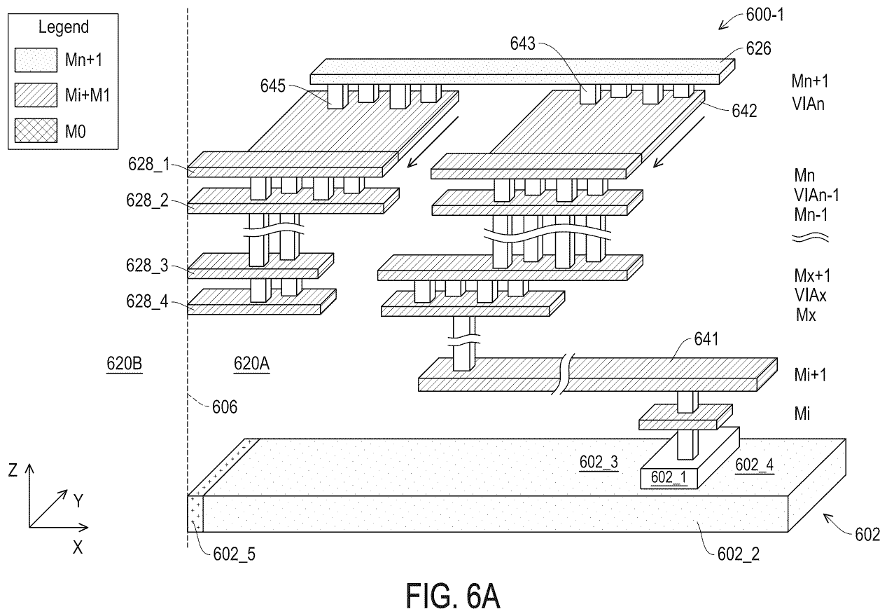

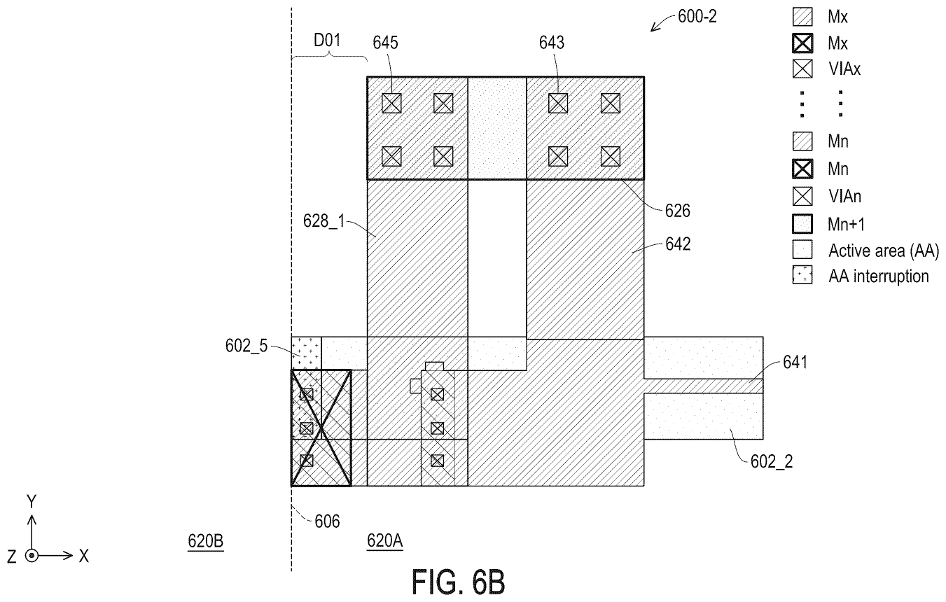

FIG. 6A is a schematic view of an IC device 600-1 according to some embodiments. FIG. 6B is a partial layout view of an IC device 600-2 according to some embodiments.

Elements of IC devices 600-1, 600-2 having a similar structure and function as elements of IC device 200 have a same identifying numeral, incremented by 400, unless stated otherwise or otherwise apparent.

Referring to FIG. 6A, the IC device 600-1 according to some embodiments includes a first cell 620A and a second cell 620B, which adjoin at a cell boundary 606. The first cell 620A includes a transistor 602 having a gate 602_1, e.g., a polysilicon gate, a high-k metal gate, or the like, over an active area 602_2, and a source 602_3 and a drain 602_4 in the active area 602_2. An active area interruption 602_5 interrupts the active area 602_2 at the cell boundary 606. In some embodiments, the active area interruption 602_5 corresponds to a dummy gate structure, a doping region, an insulating material, or the like. In some embodiments, the cell boundary 606 corresponds to a place-and-route boundary defining a region in which placement is done and where routing is constrained to. The transistor 602 is shown as a planar structure but the transistor 602 has other configurations in other embodiments, e.g., FinFet, gate all-around (GAA), complementary FET (CFET), or the like.

The gate 6021 is coupled to pin conductors 628_1˜628_4 at the cell boundary 606. The pin conductor 628_1 is in conductive layer Mn, the pin conductor 628_2 is in conductive layer Mn−1, the pin conductor 628_3 is in conductive layer Mx+1 (x+1 is less than n−1, i.e., a lower layer), and the pin conductor is in conductive layer Mx. Although not shown in FIG. 6A, in some embodiments, in the second cell 620B one or more conductors (e.g., having the length L01 and corresponding to the third conductor 232 of the IC device 200) extend in the corresponding conductive layers Mn, Mn−1, Mx+1, and/or Mx in the second cell 620B from the pin conductors 628_1˜628_4 in the first cell 620A.

In various embodiments, a pin-out for the transistor 602 is provided in any of the conductive layers Mn, Mn−1, Mx+1, and/or Mx in the IC device 600-1. By forming multiple pin-out conductors, there are multiple selections and flexibilities for electrical connections in the IC device 600-1.

The pin conductors 628_1˜628_4 are coupled to the transistor 602 by a plurality of conductors and vias, the last-formed conductor of which is a conductor 626 in a conductive layer Mn+1 that is higher than the highest pin-out layer, i.e., higher than any of the pin conductors 628_1˜628_4. Thus, the conductor 626 is formed after the pin conductor 628_1 and after any corresponding conductor(s) in the conductive layers Mn, Mn−1, Mx+1, and/or Mx in the second cell 620B. By forming the conductor 626 in a layer (layer Mn+1) that is higher than a highest layer of the pin structure (layer Mn), a conductor in the second cell 620B in the any of the pin-out layers (i.e., in any of conductive layers Mn, Mn−1, Mx+1, and/or Mx in second cell 620B) can have a length (e.g., the length L01) that is not limited by an antenna rule for the transistor 602. Further, the conductor 626 can be made shorter, e.g., to reduce a charge-accumulating area in the first cell 620A, by the distance D01 between the cell boundary 606 and the conductor 626.

In FIG. 6A, the IC device 600-1 is shown as having conductors in conductive layers Mi through Mn+1, with vias in layers therebetween (e.g., in via layer VIAn between conductive layers Mn and Mn+1, and in via layer VIAx between conductive layers Mx and Mx+1). However, a greater number of conductive layers is used in some embodiments, and a smaller number of conductive layers is used in other embodiments. Further, the pin-out of the transistor 602 is in a higher layer than the conductive layer Mn in some embodiments (although below the last-formed conductor 626, which may be in a higher layer than Mn+1), and is in a lower layer than the conductive layer Mn in other embodiments. Also, in FIG. 6A, the IC device 600-1 is shown as having four vias 645 extending vertically (parallel to the Z axis) between the pin conductor 628_1 and the overlying conductor 626. In some embodiments, fewer than four vias 645 are used, e.g., one via 645. In other embodiments, more than four vias 645 are used. Likewise, a number of vias 643 between conductor 642 in conductive layer Mn (at an opposite end of the conductor 626 from the pin conductor 628_1) is four in FIG. 6A, but is more or less in other embodiments. Also, the lengths of conductors in the conductive layers Mi˜Mn can be varied as desired. For example, whereas the IC device 200 includes a relatively long conductor in conductive layer Mi, the IC device 600-1 includes a relative short conductor in the conductive layer Mi and includes a longer conductor 641 in conductive layer Mi+1.

Referring to IC device 600-2 of FIG. 6B, the pin conductor 628_1 is offset in the Y-axis direction from the conductor 626. The conductor 642 is extended in the Y-axis direction to have a plate shape, which provides flexibility in layout, e.g., by placing some elements under the top metal layer (Mn+1). The conductor 626 is has an end that is spaced apart by distance D01 from the cell boundary. This has an advantage of reducing a charge-accumulating area of the conductor 626. Also, because at the time of fabrication of the pin conductor 628_1 it is not connected to the transistor 602 (due to the conductor 626 not having been formed yet), the length of the pin conductor 628_1 does not implicate the antenna rule of the transistor 602 when the pin conductor 628_1 is being formed. This also applies to the other pin conductors 628_2˜628_4.

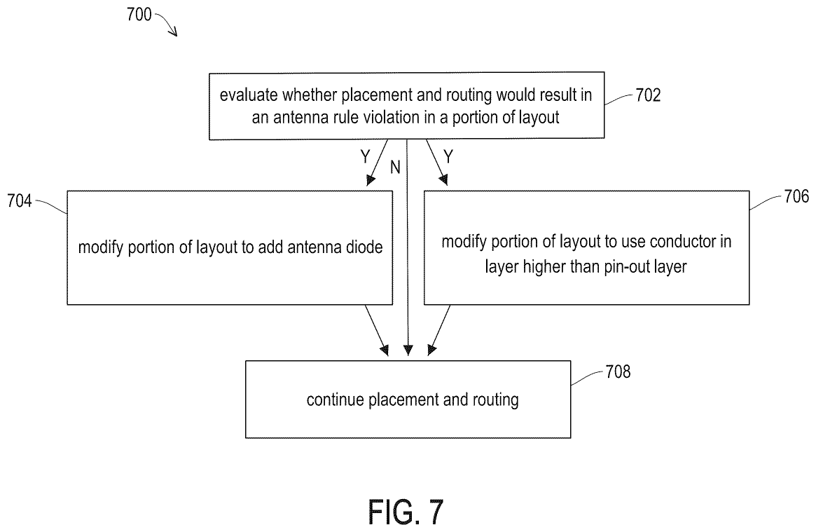

FIG. 7 is a flowchart of a method 700 of placement and routing according to some embodiments.

In method 700, the method of placement and routing includes an operation 702 of evaluating a layout of an integrated circuit design to determine whether an antenna rule violation is presented by a cell arrangement, wiring arrangement, or the like, in the layout.

If an antenna rule violation is found in operation 702, operations 704 and/or 706 are performed in some embodiments. In operation 704, an antenna rule violation is addressed, either in whole or in part, by modifying a portion of the layout to add one or more antenna diodes. In operation 706, an antenna rule violation is addressed, either in whole or in part, by modifying a portion of the layout to use connect first and second cells using conductor in layer higher than a pin-out layer. For a given antenna rule violation, the operations 704 and 706 are used in the alternative in some embodiments, and are used in combination in other embodiments.

In some embodiments, operation 704 includes, either manually or using a software tool, adding one or more antenna diodes to the IC design to provide a path for discharge of accumulated charge. In some embodiments, operation 704 includes using an assist antenna fix engine to create an engineering change order to insert a diode to address the antenna effect. The use of the assist antenna fix engine is described in U.S. patent publication no. 2023/0053711 A1, which is incorporated herein in its entirety.

In some embodiments, operation 706 includes routing a first conductive layer, e.g., a conductive layer Mi described above in connection with FIG. 2, such that a first conductor, e.g., conductor 222 in a first cell, e.g., first cell 220A, is coupled to a gate of a first transistor in the first cell. In some embodiments, operation 706 further includes routing a second conductive layer, e.g., conductive layer Mi+3, which is higher than the first conductive layer, such that: a second conductor, e.g., conductor 232, is in a second cell, e.g., second cell 220B, and adjoins a cell boundary; a pin conductor, e.g., pin conductor 228_1, is in the first cell and adjoins the cell boundary; and the second conductor extends in the second cell and is coupled between a source/drain region of a second transistor in the second cell and the pin conductor. In some embodiments, operation 706 further includes routing a third conductive layer, e.g., conductive layer Mn+1, which is higher than the second conductive layer, such that: a third conductor, e.g., conductor 226, is in the first cell and forms at least a portion of a conductive path in the first cell between the first conductor and the second conductor; and the third conductive layer is a highest conductive layer among conductive layers forming the conductive path in the first cell. In some embodiments, the third conductor is spaced apart from the cell boundary.

In some embodiments, following operations 704 and/or 706, the placement and routing continues (operation 708). In some embodiments, if no antenna rule violation is found in operation 702, the placement and routing continues (operation 708) without performing operations 704 and/or 706.

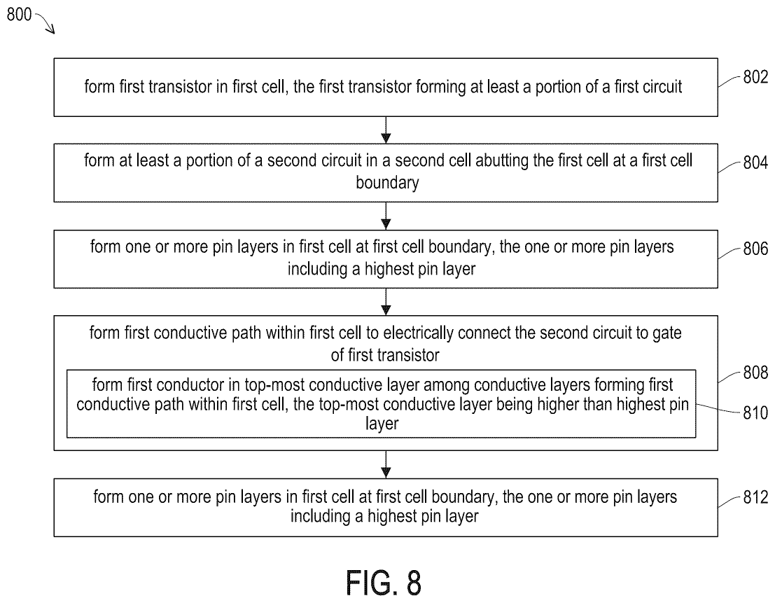

FIG. 8 is a flowchart of a method 800 of fabricating an integrated circuit device according to some embodiments.

In the method 800, an operation 802 includes forming a first transistor in a first cell, the first transistor forming at least a portion of a first circuit. An operation 804 includes forming at least a portion of a second circuit in a second cell abutting the first cell at a first cell boundary. An operation 806 includes forming one or more pin layers in the first cell at the first cell boundary, the one or more pin layers including a highest pin layer. An operation 808 includes forming a first conductive path within the first cell to electrically connect the second circuit to a gate of the first transistor; operation 808 includes a suboperation 810 of forming a first conductor in a top-most conductive layer among conductive layers forming the first conductive path within the first cell, the top-most conductive layer being a higher layer than the highest pin layer. An operation 812 includes forming a second conductor in the second cell and electrically connected to the first conductive path by a first pin layer among the one or more pin layers. In some embodiments, the method 800 is used to fabricate one or more of the IC devices 200, 400_1, 400_2, 500_1, 500_2, 600_1, and/or 600_2 described above.

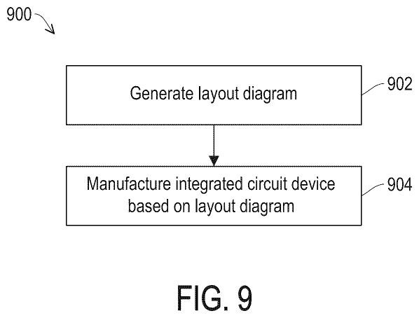

FIG. 9 is a flowchart of a method 900 of manufacturing a semiconductor device according to some embodiments.

Method 900 is implementable, for example, using EDA system 1000 (FIG. 10, discussed below) and an integrated circuit (IC), manufacturing system 1100 (FIG. 11, discussed below), in accordance with some embodiments. Examples of a semiconductor device which can be manufactured according to method 900 include one or more of the IC devices 200, 400_1, 4002, 5001, 5002, 600_1, and/or 600_2 described above.

In FIG. 9, method 900 includes blocks 902-904. At operation 902, a layout diagram is generated which, among other things, includes one or more of layout diagrams disclosed herein, or the like. In some embodiments, operation 902 includes one or more of operations 702-708 described above in connection with the method 700.

In some embodiments, the layout diagram generated in operation 902 includes: in a first conductive layer: a first conductor in a first cell, the first conductor coupled to a gate of a first transistor in the first cell; in a second conductive layer higher than the first conductive layer: a second conductor in a second cell that adjoins the first cell at a cell boundary, and a pin conductor in the first cell and adjoining the cell boundary, the second conductor extending in the second cell and being coupled between a source/drain region of a second transistor in the second cell and the pin conductor; and, in a third conductive layer higher than the second conductive layer: a third conductor in the first cell and forming at least a portion of a conductive path in the first cell between the first conductor and the second conductor, the third conductor being spaced apart from the cell boundary, the third conductive layer being a highest conductive layer among conductive layers forming the conductive path in the first cell.

Operation 902 is implementable, for example, using EDA system 1000 (FIG. 10, discussed below), in accordance with some embodiments. In some embodiments, operation 902 includes generating shapes corresponding to structures in a semiconductor diagram which are to be represented.

At operation 904, based on the layout diagram, at least one of (A) one or more photolithographic exposures are made or (B) one or more semiconductor masks are fabricated or (C) one or more components in a layer of an integrated circuit (IC) device, e.g., a semiconductor device, are fabricated. In some embodiments, operation 904 includes one or more of operations 802-812 described above in connection with the method 800. See also discussion below of FIG. 11.

FIG. 10 is a block diagram of an electronic design automation (EDA) system 1000 in accordance with some embodiments. The EDA system 1000 is usable to design one or more of the IC devices 200, 400_1, 400_2, 500_1, 500_2, 600_1, and/or 600_2 described above.

In some embodiments, the EDA system 1000 includes an APR system. In some embodiments, EDA system 1000 is or includes a general purpose computing device including a hardware processor 1002 and a non-transitory, computer-readable storage medium 1004. The computer-readable storage medium 1004 is encoded with, i.e., stores, computer program code 1006, i.e., a set of executable instructions. Execution of the instructions 1006 by the processor 1002 represents (at least in part) an EDA tool which implements a portion or all of the methods described herein in accordance with one or more embodiments (hereinafter, the noted processes and/or methods).

In some embodiments, methods described herein of designing layout diagrams representing wire routing arrangements are implementable using the EDA system 1000.

In some embodiments, the EDA system 1000 is configured to perform an APR operation to generate a layout of an IC, e.g., based on a schematic of the IC, the APR operation including a cell placement operation that places a first cell and a second cell in the layout diagram such that the first and second cells adjoin one another at a cell boundary, and a routing operation that routes a net interconnecting the first and second cells in the layout diagram, the routing operation including: routing a first conductive layer such that: a first conductor in the first cell is coupled to a gate of a first transistor in the first cell; routing a second conductive layer, which is higher than the first conductive layer, such that: a second conductor is in the second cell and adjoins the cell boundary, a pin conductor is in the first cell and adjoins the cell boundary, and the second conductor extends in the second cell and is coupled between a source/drain region of a second transistor in the second cell and the pin conductor; and routing a third conductive layer, which is higher than the second conductive layer, such that: a third conductor is in the first cell and forms at least a portion of a conductive path in the first cell between the first conductor and the second conductor, the third conductor being spaced apart from the cell boundary, and the third conductive layer is a highest conductive layer among conductive layers forming the conductive path in the first cell.

In some embodiments, execution of instructions 1006 by hardware processor 1002 represents (at least in part) an IC device design system which implements a portion or all of one or more of the noted processes and/or methods.

In some embodiments, a computer program product includes the non-transitory, computer-readable storage medium 1004 storing instructions therein that, when executed by the processor 1002, cause the processor 1002 to perform a cell placement operation that places a first cell and a second cell in the layout diagram such that the first and second cells adjoin one another at a cell boundary, and perform a first routing operation that routes a net interconnecting the first and second cells in the layout diagram, the first routing operation including: routing a first conductive layer such that: a first conductor in the first cell is coupled to a gate of a first transistor in the first cell; routing a second conductive layer, which is higher than the first conductive layer, such that: a second conductor is in the second cell and adjoins the cell boundary, a pin conductor is in the first cell and adjoins the cell boundary, and the second conductor extends in the second cell and is coupled between a source/drain region of a second transistor in the second cell and the pin conductor; and routing a third conductive layer, which is higher than the second conductive layer, such that: a third conductor is in the first cell and forms at least a portion of a conductive path in the first cell between the first conductor and the second conductor, the third conductor being spaced apart from the cell boundary, and the third conductive layer is a highest conductive layer among conductive layers forming the conductive path in the first cell. In some embodiments, the non-transitory, computer-readable storage medium 1004 further stores instructions therein that, when executed by the processor 1002, cause the processor 1002 to evaluate whether a second routing operation of the net would result in an antenna rule violation for the first transistor, and perform the first routing operation instead of the second routing operation when the evaluation determines that the second routing operation would result in the antenna rule violation for the first transistor.

The processor 1002 is electrically coupled to computer-readable storage medium 1004 via a bus 1008. The processor 1002 is also electrically coupled to an I/O interface 1010 by bus 1008. A network interface 1012 is also electrically connected to processor 1002 via bus 1008. The network interface 1012 is connected to a network 1014, so that processor 1002 and computer-readable storage medium 1004 are capable of connecting to external elements via the network 1014. The processor 1002 is configured to execute computer program code 1006 encoded in computer-readable storage medium 1004 in order to cause the EDA system 1000 to be usable for performing a portion or all of the noted processes and/or methods. In one or more embodiments, the processor 1002 is a central processing unit (CPU), a multi-processor, a distributed processing system, an application specific integrated circuit (ASIC), and/or a suitable processing unit.

In one or more embodiments, the computer-readable storage medium 1004 is an electronic, magnetic, optical, electromagnetic, infrared, and/or a semiconductor system (or apparatus or device). In some embodiments, the computer-readable storage medium 1004 includes a semiconductor or solid-state memory, a magnetic tape, a removable computer diskette, a random-access memory (RAM), a read-only memory (ROM), a rigid magnetic disk, and/or an optical disk. In one or more embodiments using optical disks, computer-readable storage medium 1004 includes a compact disc read-only memory (CD-ROM), a compact disc-read/write (CD-R/W), and/or a digital video disc (DVD).

In one or more embodiments, the computer-readable storage medium 1004 stores computer program code 1006 configured to cause the EDA system 1000 (where such execution represents (at least in part) the EDA tool) to be usable for performing a portion or all of the noted processes and/or methods. In one or more embodiments, the computer-readable storage medium 1004 also stores information that facilitates performing a portion or all of the noted processes and/or methods. In one or more embodiments, the computer-readable storage medium 1004 stores a library 1007 of standard cells including such standard cells as disclosed herein. In one or more embodiments, the computer-readable storage medium 1004 stores one or more layout diagrams 1009 corresponding to one or more layouts disclosed herein.

The EDA system 1000 includes I/O interface 1010. I/O interface 1010 is coupled to external circuitry. In one or more embodiments, I/O interface 1010 includes a keyboard, keypad, mouse, trackball, trackpad, touchscreen, and/or cursor direction keys for communicating information and commands to processor 1002.

The EDA system 1000 also includes network interface 1012 coupled to processor 1002. Network interface 1012 allows EDA system 1000 to communicate with network 1014, to which one or more other computer systems are connected. Network interface 1012 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EDA systems 1000.

The EDA system 1000 is configured to receive information through I/O interface 1010. The information received through I/O interface 1010 includes one or more of instructions, data, design rules, libraries of standard cells, and/or other parameters for processing by processor 1002. The information is transferred to processor 1002 via bus 1008. EDA system 1000 is configured to receive information related to a user interface (UI) through I/O interface 1010. The information is stored in computer-readable storage medium 1004 as UI 1042.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1000. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 11 is a block diagram of IC manufacturing system 1100, and an IC manufacturing flow associated therewith according to some embodiments. In some embodiments, based on a layout diagram, at least one of (A) one or more semiconductor masks or (B) at least one component in a layer of a semiconductor integrated circuit is fabricated using IC manufacturing system 1100.

In FIG. 11, IC manufacturing system 1100 includes entities, such as a design house 1120, a mask house 1130, and an IC manufacturer/fabricator (“fab”) 1150, that interact with one another in the design, development, and manufacturing cycles and/or services related to manufacturing an IC device 1160. The entities in IC manufacturing system 1100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of the design house 1120, the mask house 1130, and the IC fab 1150 is owned by a single larger company. In some embodiments, two or more of the design house 1120, the mask house 1130, and the IC fab 1150 coexist in a common facility and use common resources.

Design house (or design team) 1120 generates an IC design layout diagram 1122 based on the noted processes and/or methods discussed above. The IC design layout diagram 1122 includes various geometrical patterns that correspond to patterns of metal, oxide, or semiconductor layers that make up the various components of the IC device 1160 to be fabricated. The various layers combine to form various IC features. For example, a portion of the IC design layout diagram 1122 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1120 implements a proper design procedure to form the IC design layout diagram 1122. The design procedure includes one or more of logic design, physical design or place and route. The IC design layout diagram 1122 is presented in one or more data files having information of the geometrical patterns. For example, the IC design layout diagram 1122 can be expressed in a GDSII file format or DFII file format.

The mask house 1130 includes mask data preparation 1132 and mask fabrication 1144. The mask house 1130 uses the IC design layout diagram 1122 to manufacture one or more masks 1145 to be used for fabricating the various layers of the IC device 1160 according to the IC design layout diagram 1122. The mask house 1130 performs the mask data preparation 1132, where the IC design layout diagram 1122 is translated into a representative data file (RDF). Mask data preparation 1132 provides the RDF to the mask fabrication 1144. Mask fabrication 1144 includes a mask writer. A mask writer converts the RDF to an image on a substrate, such as a mask (reticle) 1145 or a substrate 1153, e.g., a semiconductor wafer. The IC design layout diagram 1122 is manipulated by the mask data preparation 1132 to comply with particular characteristics of the mask writer and/or requirements of the IC fab 1150. In FIG. 11, the mask data preparation 1132 and the mask fabrication 1144 are illustrated as separate elements. In some embodiments, the mask data preparation 1132 and the mask fabrication 1144 can be collectively referred to as mask data preparation.

In some embodiments, the mask data preparation 1132 includes optical proximity correction (OPC) which uses lithography enhancement techniques to compensate for image errors, such as those that can arise from diffraction, interference, other process effects and the like. OPC adjusts the IC design layout diagram 1122. In some embodiments, the mask data preparation 1132 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 1132 includes a mask rule checker (MRC) that checks the IC design layout diagram 1122 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1122 to compensate for limitations during the mask fabrication 1144, which may undo part of the modifications performed by OPC in order to meet mask creation rules.

In some embodiments, the mask data preparation 1132 includes lithography process checking (LPC) that simulates processing that will be implemented by the IC fab 1150 to fabricate the IC device 1160. LPC simulates this processing based on the IC design layout diagram 1122 to create a simulated manufactured device, such as the IC device 1160. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine the IC design layout diagram 1122.

It should be understood that the above description of the mask data preparation 1132 has been simplified for the purposes of clarity. In some embodiments, the mask data preparation 1132 includes additional features such as a logic operation (LOP) to modify the IC design layout diagram 1122 according to manufacturing rules. Additionally, the processes applied to the IC design layout diagram 1122 during the mask data preparation 1132 may be executed in a variety of different orders.

After the mask data preparation 1132 and during the mask fabrication 1144, a mask 1145 or a group of masks 1145 are fabricated based on the modified IC design layout diagram 1122. In some embodiments, the mask fabrication 1144 includes performing one or more lithographic exposures based on the IC design layout diagram 1122. In some embodiments, an electron-beam (e-beam) or a mechanism of multiple e-beams is used to form a pattern on a mask (photomask or reticle) 1145 based on the modified IC design layout diagram 1122. The mask 1145 can be formed in various technologies. In some embodiments, the mask 1145 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of the mask 1145 includes a transparent substrate (e.g., fused quartz) and an opaque material (e.g., chromium) coated in the opaque regions of the binary mask. In another example, the mask 1145 is formed using a phase shift technology. In a phase shift mask (PSM) version of the mask 1145, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 1144 is used in a variety of processes. For example, in some embodiments the mask(s) is used in an ion implantation process to form various doped regions in the substrate 1153, in an etching process to form various etching regions in the substrate 1153, and/or in other suitable processes.

The IC fab 1150 is an IC fabrication business that includes one or more manufacturing facilities for the fabrication of a variety of different IC products. In some embodiments, the IC fab 1150 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

The IC fab 1150 includes wafer fabrication tools 1152 configured to execute various manufacturing operations on the substrate 1153 such that the IC device 1160 is fabricated in accordance with the mask(s), e.g., the mask 1145. In some embodiments, the wafer fabrication tools 1152 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

The IC fab 1150 uses mask(s) 1145 fabricated by the mask house 1130 to fabricate the IC device 1160. Thus, the IC fab 1150 at least indirectly uses the IC design layout diagram 1122 to fabricate the IC device 1160. In some embodiments, the substrate 1153 is fabricated by the IC fab 1150 using mask(s) 1145 to form the IC device 1160. In some embodiments, the IC fabrication includes performing one or more lithographic exposures based at least indirectly on the IC design layout diagram 1122. In some embodiments, the substrate 1153 includes a silicon substrate or other proper substrate having material layers formed thereon. In some embodiments, the substrate 1153 further includes one or more of various doped regions, dielectric features, multilevel interconnects, and the like (formed at subsequent manufacturing steps).

Details regarding an IC manufacturing system (e.g., IC manufacturing system 1100 of FIG. 11), and an IC manufacturing flow associated therewith are found, e.g., in U.S. Pat. No. 9,256,709, granted Feb. 9, 2016, U.S. Pre-Grant Publication No. 2015/0278429 A1, published Oct. 1, 2015, U.S. Pre-Grant Publication No. 2014/0040838 A1, published Feb. 6, 2014, and U.S. Pat. No. 7,260,442, granted Aug. 21, 2007, the entireties of each of which are hereby incorporated by reference.

In some embodiments, an integrated circuit device includes a gate oxide-containing device (GOX device); one or more first metal layer segments and one or more first vias coupled to the GOX device; one or more second metal layer segments and one or more second vias, which are laterally spaced apart from the one or more first metal layer segments and one or more first vias; and a conductive segment forming at least part of an electrical connection that couples at least one of the one or more second metal layer segments or the one or more second vias to at least one of the one or more first metal layer segments or the one or more first vias. In some embodiments, the conductive segment is in a conductive layer that is higher than a highest pin-out layer for the GOX device. In some embodiments, the highest pin-out layer is included in the one or more second metal layer segments. In some embodiments, a conductor that is coupled to an interface pin among the one or more second metal layer segments is free of an antenna diode.

In some embodiments, a method of forming an integrated circuit device includes forming one or more first metal layer segments and one or more first vias; forming one or more second metal layer segments and one or more second vias, which are laterally spaced apart and separated from the one or more first metal layer segments and one or more first vias; performing one or more of a plasma process or a charge neutralization process such as chemical mechanical polishing (CMP) on at least one of the one or more second metal layer segments or the one or more second vias; and, after performing the charge neutralization process, coupling at least one of the one or more second metal layer segments or the one or more second vias to at least one of the one or more first metal layer segments or the one or more first vias.

In some embodiments, a method for manufacturing a semiconductor structure includes forming a first metal layer; simultaneously forming a conductive layer and a second metal layer isolated from the conductive layer, the second metal layer electrically connected to the first metal layer through a first via; forming a top metal layer electrically connected to the conductive layer and the second metal layer through a second via. In some embodiments, the first metal layer is electrically connected to a pair of transistors, and the conductive layer includes the signal routing trace and a first pin-out layer.

In some embodiments, a semiconductor structure includes a first metal layer electrically connected to a first pair of transistors; a second metal layer disposed on the first metal layer and electrically connected to the first metal layer through a first via; a conductive layer disposed in parallel with to and isolated from the second metal layer; and a top metal layer disposed on the second metal layer and the conductive layer and electrically connected to the conductive layer and the second metal layer through a second via. In some embodiments, the conductive layer includes the signal routing trace and a first pin-out layer, and the signal routing trace is electrically connected to a second pair of transistors.

In some embodiments an integrated circuit device includes: a first cell including a first transistor in an active region on a substrate, the first transistor forming at least a portion of a first circuit; and a second cell abutting the first cell at a first cell boundary, the second cell including at least a portion of a second circuit. The first cell includes one or more pin layers at the first cell boundary, the one or more pin layers including a highest pin layer, the second circuit is electrically connected to a gate of the first transistor by a first conductive path within the first cell, the first conductive path includes a first conductor in a top-most conductive layer among conductive layers forming the first conductive path within the first cell, the top-most conductive layer being a higher layer than the highest pin layer, the second circuit includes a second conductor electrically connected to the first conductive path at a first pin conductor in a first pin layer among the one or more pin layers, and the first cell boundary corresponds to at least one of an interruption in the active region, an edge of one of the one or more pin layers, or a power rail in a conductive layer closest to the substrate.

In some embodiments, the second conductor has a length L outside the first cell, and the length L is sufficient to result in a combined area of the first conductive path and the second conductor exceeding an antenna design rule check value for an antenna design rule for the gate of the first transistor. In some embodiments, the integrated circuit device further includes: a second transistor in the second cell and forming at least a portion of the second circuit. The second conductor is coupled to a source/drain region of the second transistor, and the second conductor is free of an antenna diode. In some embodiments, the first transistor and the first pin conductor are spaced apart in a first direction, the first conductor is spaced apart from the first transistor in a second direction perpendicular to the first direction, and the first conductor is spaced apart from the first pin conductor in the second direction. In some embodiments the first transistor and the first pin conductor are spaced apart in a first direction, and the first conductor is spaced apart from the first cell boundary in the first direction. In some embodiments, the one or more pin layers include a plurality of pin layers, the first conductor at least partially overlaps a second pin conductor in the highest pin layer, and at least one via extends from the first conductor to the second pin conductor. In some embodiments, the integrated circuit device further includes a stack of conductors and vias in the first cell and forming a portion of the first conductive path. Each conductor of the stack has an area that is less than an area of the first conductor. In some embodiments, the integrated circuit device further includes: a stack of conductors and vias in the first cell and forming a portion of the first conductive path. Each conductor of the stack has an area that is less than an area of the second conductor.

In some embodiments, a method of fabricating an integrated circuit device includes: forming a first transistor in an active region on a substrate, the first transistor forming at least a portion of a first circuit in a first cell; forming at least a portion of a second circuit in a second cell abutting the first cell at a first cell boundary; forming one or more pin conductors in the first cell at the first cell boundary, the one or more pin conductors including a highest pin conductor; forming a first conductive path within the first cell to electrically connect the second circuit to a gate of the first transistor, the forming the first conductive path within the first cell including: forming a first conductor in a top-most conductive layer among conductive layers forming the first conductive path within the first cell, the top-most conductive layer being a higher layer than the highest pin conductor; and forming a second conductor in the second cell and electrically connected to the first conductive path by a first pin conductor among the one or more pin conductors, the first cell boundary corresponding to at least one or an interruption in the active region, an edge of one of the one or more pin layers, or a power rail in a conductive layer closest to the substrate.

In some embodiments, the forming the one or more pin conductors includes forming the first pin conductor as the highest pin conductor. In some embodiments, the second conductor is formed to have a length L outside the first cell; and the length L is sufficient to result in a combined area of the first conductive path and the second conductor exceeding an antenna design rule check value for an antenna design rule for the gate of the first transistor. In some embodiments, the method further includes: forming a second transistor in the second cell, the second transistor forming at least a portion of the second circuit. The forming the second conductor includes coupling the second conductor to a source/drain region of the second transistor, and the second conductor is free of an antenna diode. In some embodiments, the first transistor and the first pin conductor are formed to be spaced apart in a first direction, the forming the first conductor includes: spacing the first conductor apart from the first transistor in a second direction perpendicular to the first direction, and spacing the first conductor apart from the first pin conductor in the second direction. In some embodiments, the first transistor and the first pin conductor are formed to be spaced apart in a first direction, and the forming the first conductor includes: spacing the first conductor apart from the first cell boundary in the first direction. In some embodiments, the forming the one or more pin conductors includes forming a plurality of pin conductors, the forming the first conductor includes forming the first conductor to at least partially overlap a second pin conductor in a highest pin layer, and forming at least one via extending from the first conductor to the second pin conductor. In some embodiments, the forming the first conductive path within the first cell includes: forming a stack of conductors and vias in the first cell with the conductors of the stack each having an area that is less than an area of the second conductor.

In some embodiments, an integrated circuit device includes: a first transistor in a first active region on a substrate, the first transistor being in a first cell and having a gate coupled to a first conductive segment in a first conductive layer closest to the substrate; a second transistor in a second cell adjacent to the first cell at a cell boundary, the cell boundary corresponding to at least one of an isolation structure at an edge of the first active region or a power rail in the first conductive layer; one or more pin conductors in the first cell; and a conductive path in the first cell, the conductive path coupling a first pin conductor among the one or more pin conductors to gate of the first transistor. The conductive path in the first cell includes a second conductive segment in a highest conductive layer among conductive structures forming the conductive path in the first cell, and the second conductive segment is higher than a highest pin conductor of the one or more pin conductors in the first cell.

In some embodiments, the integrated circuit device further includes: a third conductive segment in the second cell, the third conductive segment coupling the second transistor to the first pin conductor. In some embodiments, the third conductive segment has a length L in the second cell; and the length L is sufficient to result in a combined area of the conductive path and the third conductive segment exceeding an antenna design rule check value for an antenna design rule for the first transistor. In some embodiments, the third conductive segment is coupled to a source/drain region of the second transistor, and the third conductive segment is free of an antenna diode.

In some embodiments, an integrated circuit device includes a first cell including a first transistor on a substrate, the first transistor forming at least a portion of a first circuit; and a second cell abutting the first cell at a first cell boundary, the second cell including a second transistor on the substrate and forming at least a portion of a second circuit. The second circuit includes a first conductor that electrically connects a source/drain region of the second transistor to a first pin layer of a plurality of pin layers, the first cell includes a conductive path that electrically connects a gate of the first transistor to a second pin layer of the plurality of pin layers, the conductive path including a second conductor, the first pin layer is between the substrate and the second pin layer, and the second pin layer is between the second conductor and the first pin layer.

In some embodiments, a non-transitory, computer-readable storage medium includes: a layout diagram of an integrated circuit, the layout diagram including: in a first conductive layer: a first conductor in a first cell, the first conductor coupled to a gate of a first transistor in the first cell; in a second conductive layer higher than the first conductive layer: a second conductor in a second cell that adjoins the first cell at a cell boundary, and a pin conductor in the first cell and abutting the cell boundary, the second conductor extending in the second cell and being coupled between a source/drain region of a second transistor in the second cell and the pin conductor; and, in a third conductive layer higher than the second conductive layer: a third conductor in the first cell and forming at least a portion of a conductive path in the first cell between the first conductor and the second conductor, the third conductor being spaced apart from the cell boundary. The third conductive layer is a highest conductive layer among conductive layers forming the conductive path in the first cell. In some embodiments, a combined area of the first conductor, the conductive path in the first cell, and the second conductor violates an antenna rule limit for the first transistor, and a combined area of the first conductor, the third conductor, and any conductive structures in a portion of the conductive path in the first cell between the first conductor and the third conductor does not violate the antenna rule limit for the first transistor.

In some embodiments, a system includes: a processor configured to perform an Automatic Placement and Routing (APR) operation to generate a layout diagram of an integrated circuit (IC), wherein the APR operation includes: a cell placement operation that places a first cell and a second cell in the layout diagram such that the first and second cells abut one another at a cell boundary, and a routing operation that routes a net interconnecting the first and second cells in the layout diagram, the routing operation including: routing a first conductive layer such that: a first conductor in the first cell is coupled to a gate of a first transistor in the first cell; routing a second conductive layer, which is higher than the first conductive layer, such that: a second conductor is in the second cell and adjoins the cell boundary, a pin conductor is in the first cell and adjoins the cell boundary, and the second conductor extends in the second cell and is coupled between a source/drain region of a second transistor in the second cell and the pin conductor; and routing a third conductive layer, which is higher than the second conductive layer, such that: a third conductor is in the first cell and forms at least a portion of a conductive path in the first cell between the first conductor and the second conductor, the third conductor being spaced apart from the cell boundary, and the third conductive layer is a highest conductive layer among conductive layers forming the conductive path in the first cell.

In some embodiments, a computer program product includes: a non-transitory, computer-readable storage medium storing instructions therein that, when executed by a processor, cause the processor to: perform a cell placement operation that places a first cell and a second cell in a layout diagram such that the first and second cells abut one another at a cell boundary, and perform a first routing operation that routes a net interconnecting the first and second cells in the layout diagram, the first routing operation including: routing a first conductive layer such that: a first conductor in the first cell is coupled to a gate of a first transistor in the first cell; routing a second conductive layer, which is higher than the first conductive layer, such that: a second conductor is in the second cell and adjoins the cell boundary, a pin conductor is in the first cell and adjoins the cell boundary, and the second conductor extends in the second cell and is coupled between a source/drain region of a second transistor in the second cell and the pin conductor; and routing a third conductive layer, which is higher than the second conductive layer, such that: a third conductor is in the first cell and forms at least a portion of a conductive path in the first cell between the first conductor and the second conductor, the third conductor being spaced apart from the cell boundary, and the third conductive layer is a highest conductive layer among conductive layers forming the conductive path in the first cell. In some embodiments, the non-transitory, computer-readable storage medium further stores instructions therein that, when executed by the processor, cause the processor to: evaluate whether a second routing operation of the net would result in an antenna rule violation for the first transistor, and perform the first routing operation instead of the second routing operation when the evaluation determines that the second routing operation would result in the antenna rule violation for the first transistor.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless otherwise specified.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit device comprising:
a first cell including a first transistor in an active region on a substrate, the first transistor forming at least a portion of a first circuit; and
a second cell abutting the first cell at a first cell boundary, the second cell including at least a portion of a second circuit, wherein:
the first cell includes one or more pin layers at the first cell boundary, the one or more pin layers including a highest pin layer,
the second circuit is electrically connected to a gate of the first transistor by a first conductive path within the first cell,
the first conductive path includes a first conductor in a top-most conductive layer among conductive layers forming the first conductive path within the first cell, the top-most conductive layer being a higher layer than the highest pin layer,
the second circuit includes a second conductor electrically connected to the first conductive path at a first pin conductor in a first pin layer among the one or more pin layers, and
the first cell boundary corresponds to at least one of an interruption in the active region, an edge of one of the one or more pin layers, or a power rail in a conductive layer closest to the substrate.

2. The integrated circuit device of claim 1, wherein:
the second conductor has a length L outside the first cell, and
the length L is sufficient to result in a combined area of the first conductive path and the second conductor exceeding an antenna design rule check value for an antenna design rule for the gate of the first transistor.

3. The integrated circuit device of claim 2, further comprising:
a second transistor in the second cell and forming at least a portion of the second circuit,
wherein:
the second conductor is coupled to a source/drain region of the second transistor, and
the second conductor is free of an antenna diode.

4. The integrated circuit device of claim 1, wherein:
the first transistor and the first pin conductor are spaced apart in a first direction,
the first conductor is spaced apart from the first transistor in a second direction perpendicular to the first direction, and
the first conductor is spaced apart from the first pin conductor in the second direction.

5. The integrated circuit device of claim 1, wherein:
the first transistor and the first pin conductor are spaced apart in a first direction, and
the first conductor is spaced apart from the first cell boundary in the first direction.

6. The integrated circuit device of claim 1, wherein:
the one or more pin layers include a plurality of pin layers,
the first conductor at least partially overlaps a second pin conductor in the highest pin layer, and
at least one via extends from the first conductor to the second pin conductor.

7. The integrated circuit device of claim 6, further comprising:
a stack of conductors and vias in the first cell and forming a portion of the first conductive path,
wherein each conductor of the stack has an area that is less than an area of the first conductor.

8. The integrated circuit device of claim 6, further comprising:
a stack of conductors and vias in the first cell and forming a portion of the first conductive path,
wherein each conductor of the stack has an area that is less than an area of the second conductor.

9. A method of fabricating an integrated circuit device, the method comprising:
forming a first transistor in an active region on a substrate the first transistor forming at least a portion of a first circuit in a first cell;
forming at least a portion of a second circuit in a second cell abutting the first cell at a first cell boundary;
forming one or more pin conductors in the first cell at the first cell boundary, the one or more pin conductors including a highest pin conductor;
forming a first conductive path within the first cell to electrically connect the second circuit to a gate of the first transistor,
the forming the first conductive path within the first cell including:
forming a first conductor in a top-most conductive layer among conductive layers forming the first conductive path within the first cell, the top-most conductive layer being a higher layer than the highest pin conductor; and
forming a second conductor in the second cell and electrically connected to the first conductive path by a first pin conductor among the one or more pin conductors,
wherein the first cell boundary corresponds to at least one of an interruption in the active region, an edge of one of the one or more pin layers, or a power rail in a conductive layer closest to the substrate.

10. The method of claim 9, wherein:
the forming the one or more pin conductors includes forming the first pin conductor as the highest pin conductor.

11. The method of claim 9, wherein:
the second conductor is formed to have a length L outside the first cell; and
the length L is sufficient to result in a combined area of the first conductive path and the second conductor exceeding an antenna design rule check value for an antenna design rule for the gate of the first transistor.

12. The method of claim 11, further comprising:
forming a second transistor in the second cell, the second transistor forming at least a portion of the second circuit,
wherein:
the forming the second conductor includes coupling the second conductor to a source/drain region of the second transistor, and
the second conductor is free of an antenna diode.

13. The method of claim 9, wherein:
the first transistor and the first pin conductor are formed to be spaced apart in a first direction, and
the forming the first conductor includes
spacing the first conductor apart from the first transistor in a second direction perpendicular to the first direction, and
spacing the first conductor apart from the first pin conductor in the second direction.

14. The method of claim 9, wherein:
the first transistor and the first pin conductor are formed to be spaced apart in a first direction, and
the forming the first conductor includes:
spacing the first conductor apart from the first cell boundary in the first direction.

15. The method of claim 9, wherein:
the forming the one or more pin conductors includes forming a plurality of pin conductors,
the forming the first conductor includes forming the first conductor to at least partially overlap a second pin conductor in a highest pin layer, and
forming at least one via extending from the first conductor to the second pin conductor.

16. The method of claim 9, wherein:
the forming the first conductive path within the first cell includes:
forming a stack of conductors and vias in the first cell with the conductors of the stack each having an area that is less than an area of the second conductor.

17. An integrated circuit device comprising:
a first transistor in a first active region on a substrate, the first transistor being in a first cell and having a gate coupled to a first conductive segment in a first conductive layer closest to the substrate;
a second transistor in a second cell adjacent to the first cell at a cell boundary, the cell boundary corresponding to at least one of an isolation structure at an edge of the first active region or a power rail in the first conductive layer;
one or more pin conductors in the first cell;
a conductive path in the first cell, the conductive path coupling a first pin conductor among the one or more pin conductors to the gate of the first transistor; and
wherein:
the conductive path in the first cell includes a second conductive segment in a highest conductive layer among conductive structures forming the conductive path in the first cell, and
the second conductive segment is higher than a highest pin conductor of the one or more pin conductors in the first cell.

18. The integrated circuit device of claim 17, further comprising:
a third conductive segment in the second cell, the third conductive segment coupling the second transistor to the first pin conductor.

19. The integrated circuit device of claim 18, wherein:
the third conductive segment has a length L in the second cell; and
the length L is sufficient to result in a combined area of the conductive path and the third conductive segment exceeding an antenna design rule check value for an antenna design rule for the first transistor.

20. The integrated circuit device of claim 19, wherein:
the third conductive segment is coupled to a source/drain region of the second transistor, and
the third conductive segment is free of an antenna diode.
